(19) United States
(12) Patent Application Publication
(10) Pub. No.: US 2026/0351025 A1
(43) Pub. Date: Nov. 5, 2026

(54) INFORMATION PROCESSING APPARATUS, CONTROL METHOD, AND PROGRAM

(71) Applicant: SONY GROUP CORPORATION, TOKYO (JP)

(72) Inventor: KAE NAGANO, TOKYO (JP)

(21) Appl. No.: 19/488,087

(22) PCT Filed: May 2, 2024
(86) PCT No.: PCT/JP2024/016850

§ 371 Date: Nov. 26, 2025

(30) Foreign Application Priority Data
Jun. 20, 2023 (JP) 2023-100881

(51) Int. Cl. G06V 20/68; A47J 36/32; G06F 30/20

(52) U.S. Cl. CPC G06V 20/68; A47J 36/32; G06F 30/20

(57) ABSTRACT

It is possible to predict a result of cooking processing. An information processing apparatus including: a prediction unit that predicts a processing result of a food ingredient on the basis of data of the food ingredient and information regarding cooking processing for the food ingredient; and an output unit that outputs a processing result prediction image indicating the processing result predicted.

### TECHNICAL FIELD

The present disclosure relates to an information processing apparatus, a control method, and a program.

### BACKGROUND ART

In recent years, various techniques related to a cooking robot that automates a food cooking process have been disclosed. The cooking robot can proceed with cooking according to a recipe prepared in advance as control data, or reproduce a dish by realizing the same movement as the movement of the hand of the cook by using a result of sensing the movement of the cook during cooking.

In addition, Patent Document 1 discloses sensing a biological reaction when a cook makes a dish, including sensed biological data in recipe data, and providing the recipe data to a cooking robot that reproduces the dish.

### CITATION LIST

### Patent Document

Patent Document 1: Japanese Patent Application Laid-Open No. 2022-063885

### SUMMARY OF THE INVENTION

### Problems to be Solved by the Invention

However, it is difficult to predict a processing result only by experience of a cook in a current situation in which the possibility of cooking processing is further widened, such as dense processing using a digital fabrication technology.

Therefore, the present disclosure proposes an information processing apparatus, a control method, and a program capable of predicting a result of cooking processing.

### Solutions to Problems

According to the present disclosure, there is provided an information processing apparatus including: a prediction unit that predicts a processing result of a food ingredient on the basis of data of the food ingredient and information regarding cooking processing for the food ingredient; and an output unit that outputs a processing result prediction image indicating the processing result predicted.

Furthermore, according to the present disclosure, there is provided a control method including: by a processor, predicting a processing result of a food ingredient on the basis of data of the food ingredient and information regarding cooking processing for the food ingredient; and outputting a processing result prediction image indicating the processing result predicted.

Furthermore, according to the present disclosure, there is provided a program for causing a computer to function as: a prediction unit that predicts a processing result of a food ingredient on the basis of data of the food ingredient and information regarding cooking processing for the food ingredient; and an output unit that outputs a processing result prediction image indicating the processing result predicted.

### BRIEF DESCRIPTION OF DRAWINGS

FIG. 1 is a diagram illustrating an overall configuration of a cooking system according to one embodiment of the present disclosure.

FIG. 2 is a block diagram illustrating an example of a configuration of an information processing apparatus 10 according to the present embodiment.

FIG. 3 is a diagram schematically illustrating a processing example of a food ingredient.

FIG. 4 is a diagram for explaining learning input data used for generating a first processing prediction model according to the present embodiment.

FIG. 5 is a flowchart illustrating an example of a flow of generation processing of a first processing prediction model according to the present embodiment.

FIG. 6 is a flowchart illustrating an example of a flow of prediction (image generation) processing using a first processing prediction model of the present embodiment.

FIG. 7 is a diagram for explaining learning input data used for generating a second processing prediction model according to the present embodiment.

FIG. 8 is a flowchart illustrating an example of a flow of generation processing of a second processing prediction model according to the present embodiment.

FIG. 9 is a flowchart illustrating an example of a flow of prediction (image generation) processing using a second processing prediction model of the present embodiment.

FIG. 10 is a diagram for explaining learning input data used for generating a third processing prediction model according to the present embodiment.

FIG. 11 is a flowchart illustrating an example of a flow of generation processing of a third processing prediction model according to the present embodiment.

FIG. 12 is a flowchart illustrating an example of a flow of prediction (image generation) processing using a third processing prediction model according to the present embodiment.

FIG. 13 is a diagram illustrating a presentation example of a processing result prediction image according to the present embodiment.

FIG. 14 is a diagram illustrating another presentation example of a processing result prediction image according to the present embodiment.

FIG. 15 is a diagram illustrating a presentation example of a processing pattern prediction image according to the present embodiment.

FIG. 16 is a diagram illustrating another presentation example of a processing result prediction image according to the present embodiment.

FIG. 17 is a diagram illustrating a presentation example of a processing result prediction image for each parameter at the time of cooking processing according to the present embodiment.

FIG. 18 is a diagram for explaining a food ingredient having a layer structure according to the present embodiment.

FIG. 19 is a diagram for explaining learning input data used for generating a processing prediction model corresponding to a layer structure according to the present embodiment.

FIG. 20 is a flowchart illustrating an example of a flow of generation processing of a processing prediction model corresponding to a layer structure according to the present embodiment.

FIG. 21 is a diagram illustrating an example of a capture screen in the design tool screen according to the present embodiment.

FIG. 22 is a diagram illustrating an example of a topping screen in the design tool screen according to the present embodiment.

FIG. 23 is a diagram illustrating an example of a topping 3 addition screen according to the present embodiment.

FIG. 24 is a diagram illustrating an example of a topping screen in the design tool screen according to the present embodiment.

FIG. 25 is a diagram for explaining arrangement in consideration of margins of each topping according to the present embodiment.

FIG. 26 is a flowchart illustrating operation processing of a cooking design (layout of cake topping) according to the present embodiment.

FIG. 27 is a diagram illustrating an example of a design creation screen of a salad plate according to the present embodiment.

FIG. 28 is a flowchart illustrating operation processing of a cooking design (design of a Voronoi pattern of a base food ingredient in a salad plate) according to the present embodiment.

FIG. 29 is a diagram illustrating an example in which mechanical characteristics (hardness) of texture according to the present embodiment are combined.

FIG. 30 is a diagram for explaining a cooking design of a container-type food ingredient according to the present embodiment.

FIG. 31 is a flowchart illustrating an example of a flow of generation processing of a design of a container-type food ingredient according to the present embodiment.

### MODE FOR CARRYING OUT THE INVENTION

Hereinafter, a preferred embodiment of the present disclosure will be described in detail with reference to the accompanying drawings. Note that, in the present specification and the drawings, components having substantially the same functional configuration are denoted by the same reference signs, and redundant description is omitted.

Further, the description will be given in the following order.
1. Overview of Cooking System According to One Embodiment of Present Disclosure
2. Configuration Example of Information Processing Apparatus 10
3. Processing Prediction
   3-1. First Processing Prediction Model
   3-2. Second Processing Prediction Model
   3-3. Third Processing Prediction Model
   3-4. Utilization Example of Processing Prediction Model
   3-5. Others
4. Presentation of Cooking Design Proposal
   4-1. First Cooking Design Presentation Example
   (1) Arrangement of Main Topping
   (2) Selection of Topping
   (3) Presentation of Proposed Design
   (4) Cooking Processing Control
   (5) Setting
   (6) Operation Processing
   4-2. Second Cooking Design Presentation Example
   (1) Design Creation Screen
   (2) Operation Processing
   4-3. Third Cooking Design Presentation Example
5. Supplement

### <<1. Overview of Cooking System According to One Embodiment of Present Disclosure>>

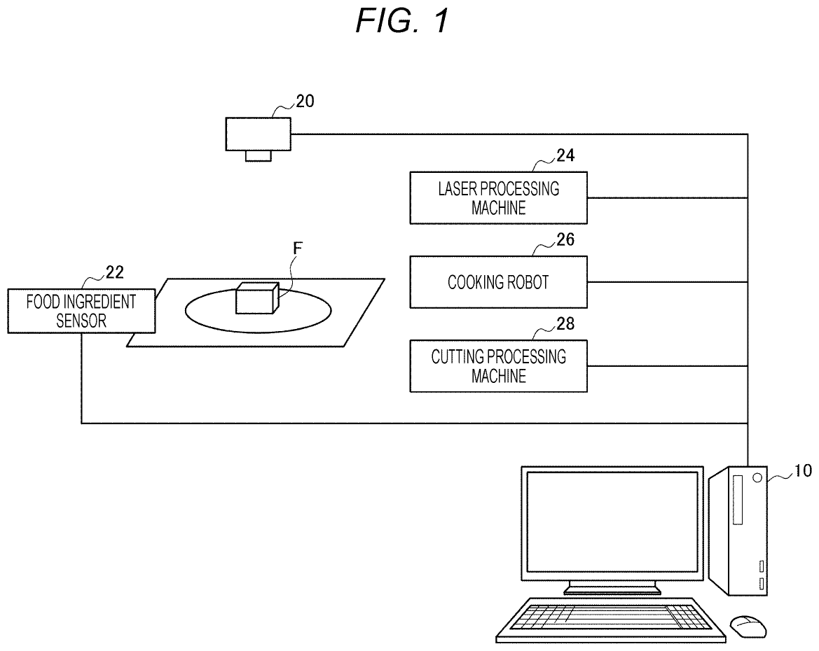

With reference to FIG. 1, an overview of a cooking system according to one embodiment of the present disclosure will be described. FIG. 1 is a diagram illustrating an overall configuration of a cooking system according to one embodiment of the present disclosure.

As illustrated in FIG. 1, the cooking system according to the present embodiment includes a camera 20, a food ingredient sensor 22, a laser processing machine 24, a cooking robot 26, a cutting processing machine 28, and an information processing apparatus 10.

The camera 20 captures an image of the food ingredient F placed on the cooking table and outputs the captured image to the information processing apparatus 10. The type of the food ingredient can be recognized by analyzing the captured image in the information processing apparatus 10. Furthermore, the 2D or 3D shape and arrangement of the food ingredient can be recognized by analysis of the captured image in the information processing apparatus 10. The food ingredient sensor 22 senses various components (for example, moisture, sugar content, and the like), a state (for example, temperature), or the like of the food ingredient F, and outputs sensing data to the information processing apparatus 10. Note that the camera 20 and the food ingredient sensor 22 are examples of sensors included in the cooking system, and the present embodiment is not limited thereto.

The information processing apparatus 10 is communicably connected to the camera 20, the food ingredient sensor 22, the laser processing machine 24, the cooking robot 26, the cutting processing machine 28, and the like, and transmits and receives information. The information processing apparatus 10 is realized by, for example, a personal computer (PC), a tablet terminal, a smartphone, a head mounted display (HMD), or the like.

The laser processing machine 24 can draw characters, patterns, marks, and the like on the food ingredient F by irradiating the food ingredient F with a laser and burning the food ingredient F, or can engrave characters, patterns, marks, and the like on the food ingredient F by scraping the food ingredient F with a laser. The cooking robot 26 has one or more robot arms, and can perform various cooking by gripping various food ingredients and arranging them at predetermined positions, applying seasoning, pouring a sauce, or using various cooking utensils. The cutting processing machine 28 can cut the food ingredient F with a computer numerical control (CNC) milling machine, a laser, or the like. The laser processing machine 24, the cooking robot 26, and the cutting processing machine 28 are digital fabrication devices that can precisely perform cutting, engraving, heating, lamination, various cooking processes, and the like on the basis of digital data. In addition, the laser processing machine 24, the cooking robot 26, and the cutting processing machine 28 are examples of processing devices that perform various cooking processing, and the configuration of the cooking system is not limited thereto.

### Summary of Problems

In recent years, with the development of digital fabrication technology, highly accurate cutting, heating, or the like can be performed as compared with conventional cooking methods, and the possibility of cooking design is widened. However, it is a high hurdle for cooks to come up with new dishes using digital fabrication technologies. For example, complex changes in food ingredients caused by dense processing using a digital fabrication device are difficult to predict based on the experience of cooks. Examples of changes in food ingredients include, for example, browning and coloring due to heating processing, deformation of the food ingredient (such as swelling, melting, or chipping), edge conditions due to cutting processing, and deformation of the food ingredient (such as bending, breaking, or chipping).

As described above, it is difficult to predict the processing result only by the experience of the cook in the current situation in which the possibility of cooking processing is further widened due to the dense processing using the digital fabrication technology or the like.

Therefore, the present disclosure proposes an information processing apparatus capable of predicting a result of cooking processing.

Specifically, the information processing apparatus 10 according to the present embodiment predicts a processing result of a food ingredient on the basis of data of the food ingredient and information regarding cooking processing for the food ingredient, and outputs a processing result prediction image indicating a processing result prediction when predetermined cooking processing is performed on the food ingredient, thereby supporting trial and error of new cooking designs utilizing the digital fabrication technology by the user. This makes it possible, for example, for chefs of small-scale restaurants, cooking experts, or the like to consider new cooking designs utilizing digital fabrication. In addition, it is also possible to make food ingredients easier to chew by processing using digital fabrication, and it can be used when improving chopped food for the elderly, infants, or patients.

The overview of the cooking system according to one embodiment of the present disclosure has been described above. Subsequently, the information processing apparatus 10 included in the cooking system according to the present embodiment will be specifically described with reference to the drawings.

### <<2. Configuration Example of Information Processing Apparatus 10>>

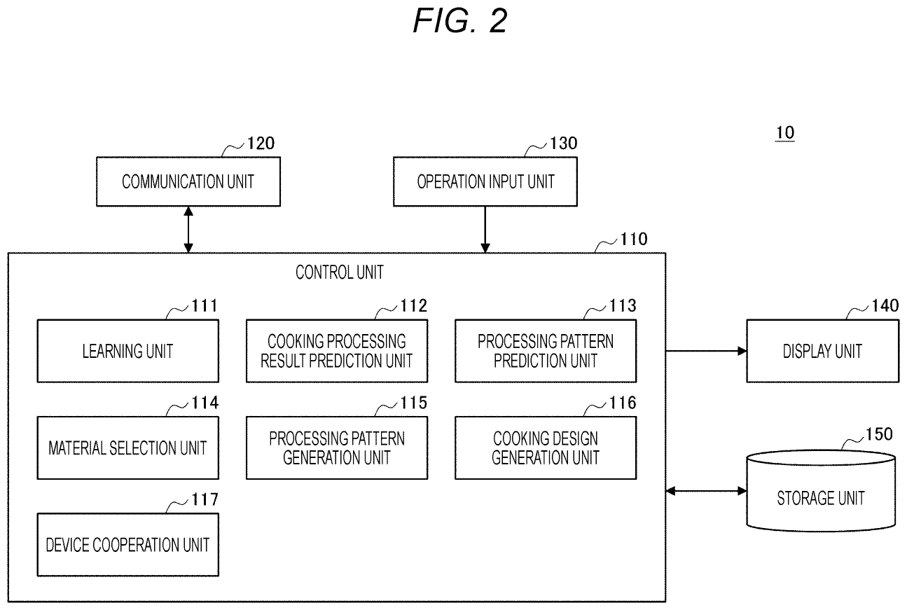

FIG. 2 is a block diagram illustrating an example of a configuration of the information processing apparatus 10 according to the present embodiment. As illustrated in FIG. 2, the information processing apparatus 10 includes a control unit 110, a communication unit 120, an operation input unit 130, a display unit 140, and a storage unit 150.

### (Communication Unit 120)

The communication unit 120 includes a transmission unit that transmits data to an external apparatus and a reception unit that receives data from the external apparatus. The communication unit 120 according to the present embodiment is communicably connected to the camera 20, transmits an imaging control signal to the camera 20, and receives a captured image from the camera 20. The communication unit 120 is communicably connected to the food ingredient sensor 22, transmits a control signal to the food ingredient sensor 22, and receives sensing data from the food ingredient sensor 22.

The communication unit 120 is communicably connected to various digital fabrication devices (laser processing machine 24, cooking robot 26, and cutting processing machine 28), and transmits a control signal for controlling various cooking operations.

The communication unit 120 may be communicably connected to an external apparatus or the Internet using, for example, a wired/wireless local area network (LAN), Wi-Fi (registered trademark), Bluetooth (registered trademark), a mobile communication network (Long Term Evolution (LTE), 5G (5th generation mobile communication system)), or the like.

### (Operation Input Unit 130 and Display Unit 140)

The operation input unit 130 receives an operation input by the user and outputs input information to the control unit 110. The operation input unit 130 may be realized by a mouse, a keyboard, a switch, a button, or the like. In addition, the display unit 140 displays various operation screens and a processing result prediction image to be described later. The display unit 140 may be a display panel such as a liquid crystal display (LCD) or an organic electro luminescence (EL) display. Furthermore, the operation input unit 130 and the display unit 140 may be integrally provided. The operation input unit 130 may be a touch sensor laminated on the display unit 140 (for example, a panel display).

### (Control Unit 110)

The control unit 110 functions as an arithmetic processing apparatus and a control apparatus, and controls the overall operation in the information processing apparatus 10 according to various programs. The control unit 110 is realized by, for example, an electronic circuit such as a central processing unit (CPU), a graphics processing unit (GPU), or a microprocessor. Furthermore, the control unit 110 may include a read only memory (ROM) that stores programs to be used, operation parameters, and the like, and a random access memory (RAM) that temporarily stores parameters and the like that change appropriately.

Furthermore, the control unit 110 according to the present embodiment can also function as the learning unit 111, the cooking processing result prediction unit 112, the processing pattern prediction unit 113, the material selection unit 114, the processing pattern generation unit 115, the cooking design generation unit 116, and the device cooperation unit 117.

The learning unit 111 generates a processing prediction model by machine learning. Complex changes in food ingredients caused by precise processing using a digital fabrication device are difficult to predict based on the experience of cooks, because there are many reactions, such as the Maillard reaction, that have not yet been fully elucidated. Therefore, in the present embodiment, the learning unit 111 learns a relationship between a pattern (hereinafter, referred to as a processing pattern) of cooking processing such as cutting, engraving, or heating performed on a food ingredient and a processing result captured image obtained by capturing a result of cooking processing of the food ingredient according to each processing pattern, and generates a processing prediction model. Details of the processing prediction model generation will be described later.

The cooking processing result prediction unit 112 uses the processing prediction model generated by the learning unit 111 to predict the cooking processing result when predetermined cooking processing is performed on the food ingredient designated by the user. The user may designate the food ingredient to be processed by inputting the type of the food ingredient, or may image the actual food ingredient to be processed with the camera 20 and input the captured image. The cooking processing result prediction unit 112 predicts the cooking processing result using the processing prediction model described above on the basis of the data of the food ingredient (the type of food ingredient or the like) and the information regarding the cooking processing on the food ingredient (for example, a processing pattern).

The cooking processing result prediction unit 112 generates a processing result prediction image indicating the processing result prediction as the prediction of the cooking processing result. The processing result prediction image may be a 2D image or a 3D image. Furthermore, the processing result prediction image may be computer graphics (CG), or may be a processing result captured image prepared in advance (an image obtained by capturing a result of actually cooking and processing a food ingredient) or an image newly generated on the basis of the processing result captured image.

The control unit 110 also functions as an output unit that outputs the processing result prediction image indicating the processing result prediction generated by the cooking processing result prediction unit 112 to the display unit 140.

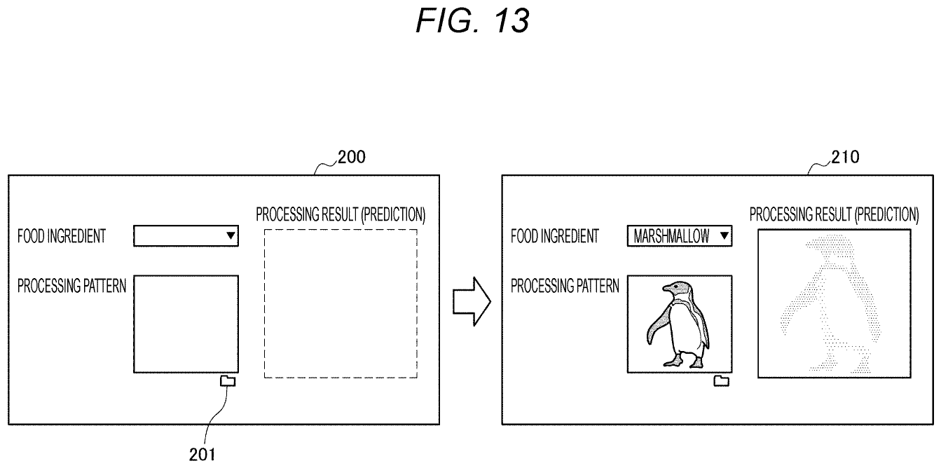

The processing pattern prediction unit 113 predicts a processing pattern to be input to the digital fabrication device from a food ingredient designated by the user (for example, the food ingredient F illustrated in FIG. 1) and a processing result desired by the user (specifically, the processing result captured image selected by the user) using the processing prediction model generated by the learning unit 111. By presenting the processing pattern from the processing result desired by the user, it is possible to support the user who considers a new cooking design using the digital fabrication device. Details will be described later with reference to FIG. 13.

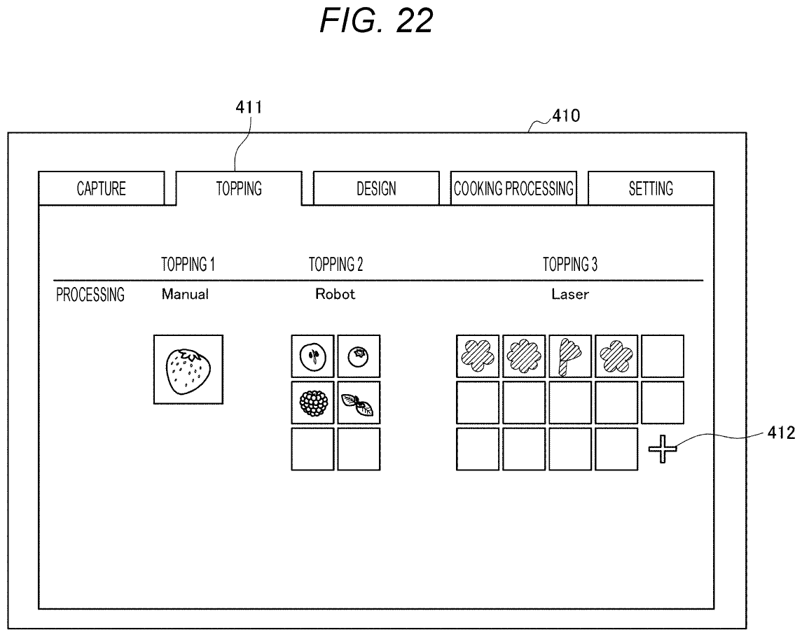

The material selection unit 114 selects a candidate of a material suitable as a sub for a main food ingredient (for example, a food ingredient F illustrated in FIG. 1). The material selection unit 114 may predict a material having a high use frequency as a sub by using a model learned from a cooking history of the user, or may analyze cooking recipe data (French Cuisine, Japanese Cuisine, or the like) for each genre to select a material having a high use frequency as a sub. As a result, when the user considers a new cooking design, it is possible to propose a sub material for the main food ingredient designated by the user. Details will be described later with reference to FIG. 22.

The processing pattern generation unit 115 generates a processing pattern for cooking processing (cutting, engraving, heating, lamination, and the like) using the digital fabrication device. The processing pattern generation unit 115 may predict a processing pattern of a pattern matching the user's preference using a model that has learned a history of designs and patterns of the user's past dishes. In this way, by predicting the processing pattern using the model generated by learning the user's past dish, it is possible to support the user who considers a new cooking design using the digital fabrication device.

The cooking design generation unit 116 generates a design (hereinafter, also referred to as a cooking design) of the entire dish using the food ingredients designated by the user. The food ingredient designated by the user may be a food ingredient designated from the operation screen displayed on the display unit 140, or may be the food ingredient F captured by the camera 20. The control unit 110 can analyze the captured image obtained by imaging the food ingredient F and recognize the type, position, shape, and the like of the food ingredient F. Furthermore, in addition to the type of food ingredient, information regarding the shape of the food ingredient (for example, “sliced radish”, “salmon fillet”, and the like) may be input from the operation screen.

Hereinafter, generation examples of cooking designs by the cooking design generation unit 116 will be described with some examples.

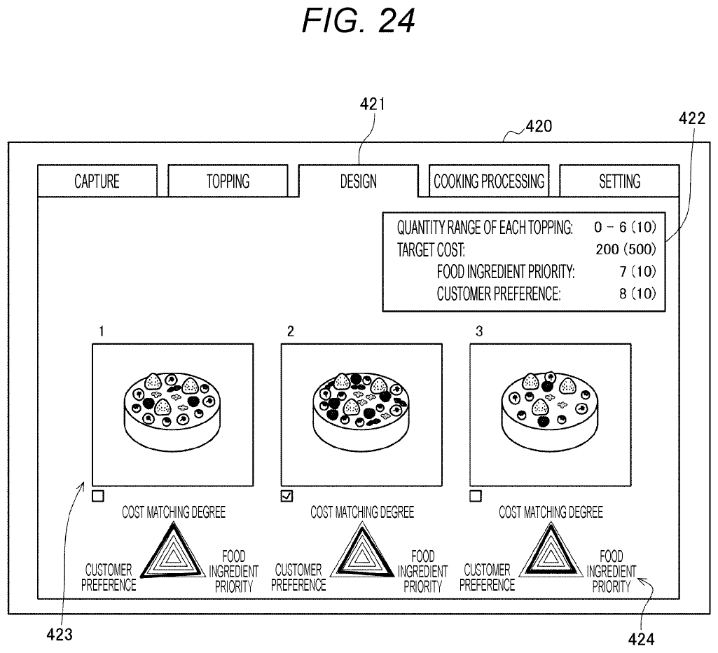

Based on the food ingredient F (main food ingredient) imaged by the camera 20, the cooking design generation unit 116 generates a cooking design by combining the candidates of the material (sub material) selected by the material selection unit 114 and the processing pattern generated by the processing pattern generation unit 115. Although the details will be described with reference to FIG. 24, for example, the cooking design generation unit 116 performs a topping layout on a cake or performs a serving design of a plurality of food ingredients on a dish as the generation of the cooking design. The layout of each material may be performed using a predetermined algorithm. Furthermore, the cooking design generation unit 116 may generate a new cooking design by using a model obtained by learning a design style frequently used by the user from a cooking history of the user or the like.

The cooking design generation unit 116 can also generate a cooking design using cooking processing (cutting, engraving, heating, lamination, and the like) by the digital fabrication device. Furthermore, when arranging a plurality of food ingredients, the cooking design generation unit 116 considers not only the design property but also the device operation margin at the time of cooking processing. The device operation margin also includes a range of thermal influence and the like.

The cooking design generation unit 116 can simulate the generated cooking design by using the 3D model corresponding to each material, generate a cooking design image (2D image or 3D image), and display the cooking design image on the display unit 140. Furthermore, when generating the cooking design image, the cooking design generation unit 116 may use the prediction result (cooking processing result predicted on the basis of the processing pattern and the food ingredient data) by the cooking processing result prediction unit 112.

Furthermore, the cooking design generation unit 116 can also output a cooking design optimized to satisfy one or more cooking conditions input by the user. For example, the cooking design generation unit 116 may change a predetermined parameter within a predetermined range to generate a plurality of cooking designs, and present a predetermined number of cooking designs most suitable for cooking conditions among the cooking designs to the user as suitable cooking designs. Furthermore, the cooking design generation unit 116 may make a plurality of combinations of sub materials, generate each cooking design using a predetermined number of combinations most suitable for cooking conditions among the combinations, and present the cooking designs to the user.

Examples of the cooking condition include a type of a food ingredient that the user wants to mainly use, a purpose of cooking, a food ingredient that the user wants to preferentially use, a design concept, information of a customer who is the recipient of the dish (customer's preference, allergy, age, chewing difficulty, or the like), a combination of food ingredients, congeniality between food ingredients, a balance of an amount of food ingredients, a nutrient balance, a food loss (food ingredient inventory consumption and the like), a shape design, an arrangement, an atmosphere of serving, a golden ratio of a food ingredient and a sauce, ease of eating, a texture, a change in taste or texture, a state of a sauce, a visual effect, a processing restriction (processing restriction time in consideration of time of deterioration or deformation (melting or solidifying) of food ingredient, mutual influence between food ingredients, and the like), a cost target, and the like.

As described above, in the present embodiment, it is possible to support generation of a new cooking design by proposing a cooking design in consideration of various cooking conditions input by the user. Further, in the present embodiment, it is also possible to present a cooking design proposal using a digital fabrication device.

The control unit 110 also functions as an output unit that outputs the cooking design image (an example of the processing result prediction image) generated by the cooking design generation unit 116 to the display unit 140.

The device cooperation unit 117 performs control to convert the generated cooking design into a format that can be recognized by the digital fabrication device and transmit the converted cooking design from the communication unit 120 to each digital fabrication device (cooking device). Each digital fabrication device can perform various cooking operations (including cooking processing such as cutting, engraving, or heating) according to a format. In addition, the device cooperation unit 117 may generate a parameter (control signal) that defines various cooking operations for realizing the generated cooking design, and transmit the parameter to each digital fabrication device.

### (Storage Unit 150)

The storage unit 150 is realized by a ROM that stores programs, operation parameters, and the like used for processing of the control unit 110, and a RAM that temporarily stores parameters and the like that change as appropriate.

For example, the storage unit 150 may store a processing prediction model generated by the learning unit 111, learning data used to generate the processing prediction model, a cooking history of the user, a processing pattern registered in advance, information on a cooperating digital fabrication device, and the like.

The configuration of the information processing apparatus 10 has been specifically described above. Note that the configuration of the information processing apparatus 10 according to the present disclosure is not limited to the example illustrated in FIG. 2. For example, the information processing apparatus 10 may be implemented by a plurality of apparatuses. Furthermore, at least a part of the functions of the information processing apparatus 10 may be realized by a server on the Internet. Furthermore, the information processing apparatus 10 may not include the learning unit 111, and may use a learned processing prediction model prepared in advance.

### <<3. Processing Prediction>>

Next, processing prediction according to the present embodiment will be described.

As described above, in a case where precise processing is performed by the digital fabrication device, complicated food ingredient changes may occur. For example, in a case where a processing pattern is burned on a marshmallow by laser processing (for example, in a case where a butterfly pattern is raster-processed), fine lines can be accurately reproduced, but the temperature rises due to the laser reaction and the marshmallow expands, whereby the white line portion expands, or the lines of the burned processing pattern are deformed or crushed. In addition, charring may not be uniform. In addition, for example, in the case of processing lasagna (sheet-like wide and flat pasta noodles), the laser irradiation portion may be widely burnt, and the fine portion of the processing pattern may be crushed. As described above, even if highly accurate processing by the digital fabrication device is possible, the change in the food ingredient due to the processing is complicated, and the user cannot easily predict the change.

In addition, for example, in a case where a processing pattern is burned onto a salmon fillet by laser processing, the laser absorption reaction in the white striped portion (striation) of the salmon differs from that in the red meat portion, and only the red meat portion changes color while the white striped portion remains unchanged, so the processing pattern may be interrupted at the white striped portion, or depending on the position or thickness of the stripes, the processing pattern may become difficult to recognize. As described above, in a case where the processing reaction is not uniform due to the component distribution of the food ingredient, it is more difficult to predict the processing result.

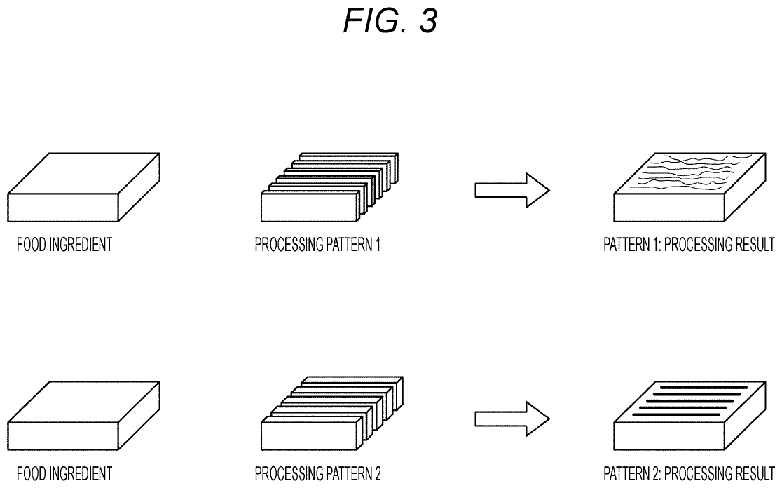

In addition, in a case of cutting a food ingredient with a digital fabrication device (for example, a CNC milling machine), depending on the width of a processing pattern, moisture may flow out from the food ingredient during cutting or become soft, and the cutting line may be bent. FIG. 3 is a diagram schematically illustrating a processing example of a food ingredient. FIG. 3 illustrates a result of cutting the same food ingredient (for example, cube-shaped carrots) in processing patterns (line patterns) having different line widths. The processing pattern 1 has a thin line width, and the processing pattern 2 has a thick line width. In this case, as illustrated in the lower part of FIG. 3, in a case where the line width of the processing pattern 2 is thick, cutting can be performed substantially linearly as in the pattern. However, as illustrated in the upper part of FIG. 3, in a case where the line width of the processing pattern 1 is thin, moisture flows out from the food ingredient or the food ingredient becomes soft during cutting, and the pattern is bent.

As described above, while highly accurate cooking processing by the digital fabrication device is possible, it is difficult to grasp complicated food ingredient changes that may occur due to the cooking processing by the user's conventional cooking experience. Therefore, in the present embodiment, a change in a food ingredient due to cooking processing, that is, a processing result is predicted, and a processing result prediction image is presented to a user, thereby supporting examination of a new cooking design utilizing a digital fabrication technology.

Specifically, in the information processing apparatus 10 according to the present embodiment, the learning unit 111 learns the relationship between the plurality of processing patterns and the processing result captured image obtained by capturing the result of cooking and processing the food ingredient according to each processing pattern, thereby generating the processing prediction model. Furthermore, in the information processing apparatus 10, the cooking processing result prediction unit 112 predicts a result of cooking processing (generates a processing result prediction image) using the processing prediction model.

Hereinafter, a processing prediction model according to the present embodiment will be described with reference to the drawings.

### <3-1. First Processing Prediction Model>

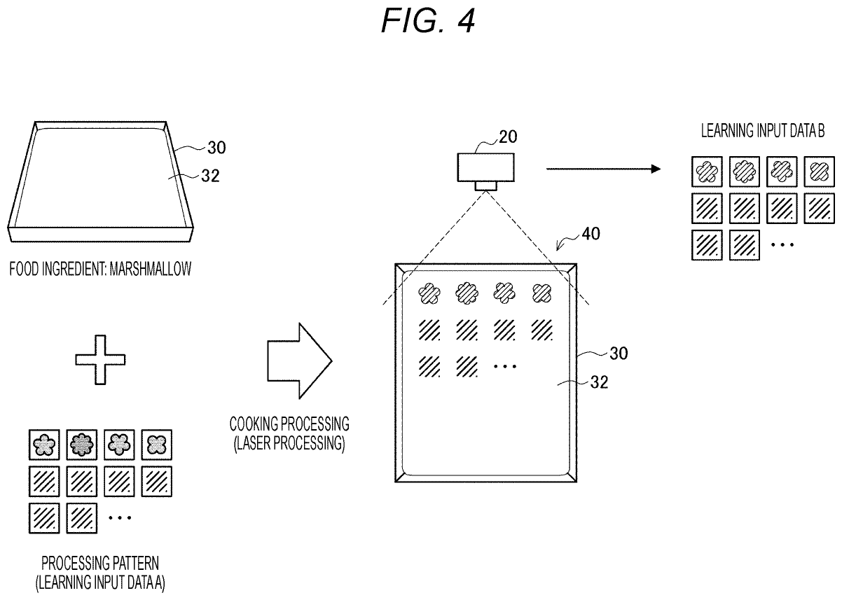

The learning unit 111 learns by using a result of actually processing the food ingredient. FIG. 4 is a diagram for explaining learning input data used for generation of a first processing prediction model according to the present embodiment. A user prepares a food ingredient to be processed and a plurality of different processing patterns. In the example illustrated in FIG. 4, a marshmallow 32 large enough for a tray 30 is used as the food ingredient to be processed.

Next, cooking processing (laser processing) of burning each processing pattern with a laser by the laser processing machine 24 is performed on the marshmallow 32, and the cooking processing result 40 is imaged by the camera 20. The captured image is transmitted to the information processing apparatus 10.

The learning unit 111 of the information processing apparatus 10 creates learning input data A (for example, a pattern image of 256 pixels×256 pixels) from each processing pattern.

In addition, the learning unit 111 creates learning input data B (cooking processing result image corresponding to each processing pattern, having the same size as the pattern image) from the captured image obtained by capturing the cooking processing result 40. The learning unit 111 creates the learning input data B by dividing the captured image obtained by imaging the entire marshmallow 32 into images having the same size as the pattern image. In creating the learning input data A and the learning input data B, the learning unit 111 rotates and extends the processing pattern and the data of the captured image as necessary.

Then, the learning unit 111 learns a relationship between the learning input data A (pattern image) generated from the processing pattern and the learning input data B (cooking processing result image) generated from the captured image of the cooking processing result, and generates a processing prediction model (first processing prediction model).

### (Operation Processing)

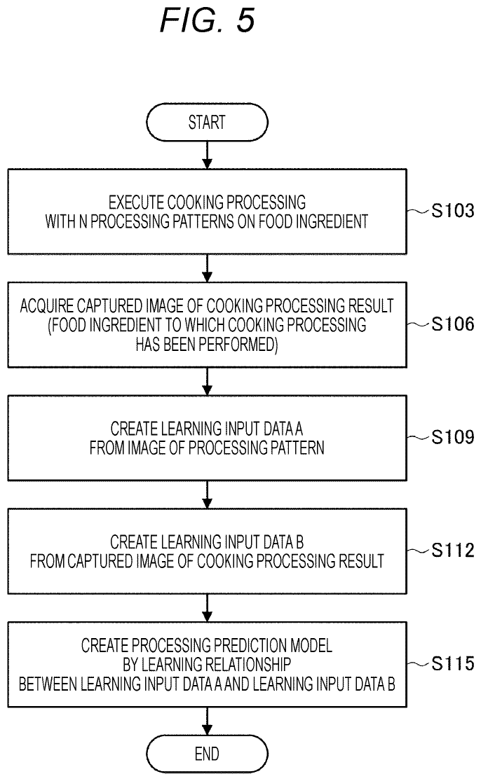

FIG. 5 is a flowchart illustrating an example of a flow of generation processing of the first processing prediction model according to the present embodiment.

As illustrated in FIG. 5, first, the control unit 110 of the information processing apparatus 10 performs cooking processing with N processing patterns on the food ingredient by the digital fabrication device (step S103). The N processing patterns may be set by the user or may be automatically set by the control unit 110.

Next, the control unit 110 acquires the captured image of the cooking processing result (the food ingredient for which the cooking processing has been performed) from the camera 20 (step S106). The imaging operation of the camera 20 may be manually performed by the user or may be performed by the control unit 110.

Next, the learning unit 111 of the information processing apparatus 10 creates learning input data A from the image of the processing pattern (step S109).

Next, the learning unit 111 creates learning input data B from the captured image of the cooking processing result (step S112).

Then, the learning unit 111 creates a processing prediction model (first processing prediction model) by learning the relationship between the learning input data A and the learning input data B (step S115). The learning unit 111 can create such a processing prediction model for each food ingredient. In addition, the created processing prediction model is stored in the storage unit 150.

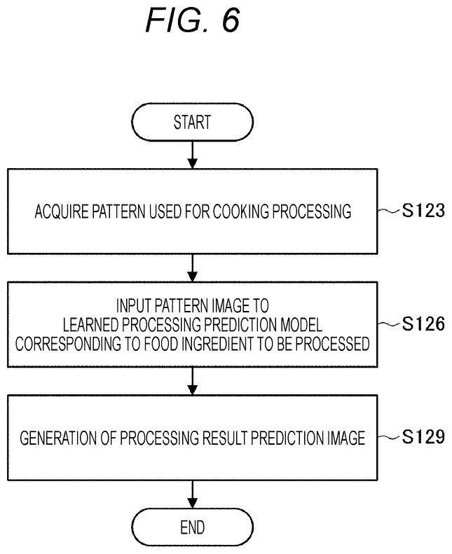

FIG. 6 is a flowchart illustrating an example of a flow of prediction (image generation) processing using the first processing prediction model of the present embodiment.

As illustrated in FIG. 6, first, the cooking processing result prediction unit 112 of the information processing apparatus 10 acquires a processing pattern used for cooking processing (step S123). The processing pattern used for cooking processing is designated by the user from, for example, an operation screen displayed on the display unit 140 of the information processing apparatus 10.

Next, when the cooking processing result prediction unit 112 inputs the pattern image of the acquired processing pattern described above to the learned processing prediction model (first processing prediction model) corresponding to the food ingredient to be processed (step S126), the processing result prediction image is output from the learned processing prediction model (step S129). In this manner, the cooking processing result prediction unit 112 can generate the processing result prediction image by using the learned processing prediction model.

### <3-2. Second Processing Prediction Model>

In a case where the state of the surface of the food ingredient is uniform and the individual difference of the food ingredient is small as in the marshmallow used in the description of the first processing prediction model, the processing prediction model can be generated by learning the relationship between the processing pattern (pattern image) and the captured image of the cooking processing result. However, there may be a food ingredient having individual differences and affecting the processing result (having individual differences in the processing result) such as stripes of salmon.

In the case of such a food ingredient having an individual difference, the learning unit 111 can generate a more accurate processing prediction model by further learning the relationship between the food ingredient before processing and the cooking processing result.

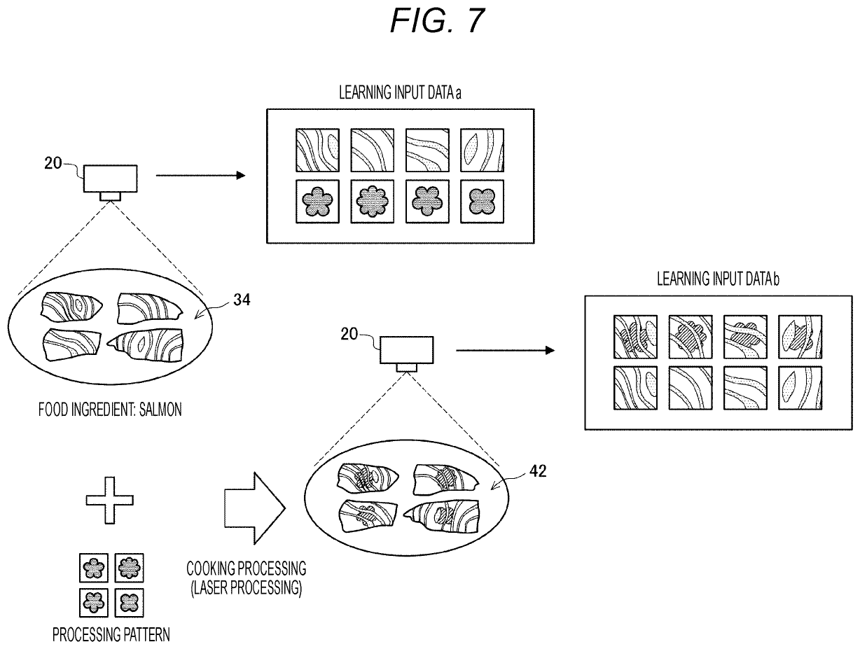

FIG. 7 is a diagram for explaining learning input data used for generation of a second processing prediction model according to the present embodiment. A user prepares a food ingredient to be processed and a plurality of different processing patterns. In the example illustrated in FIG. 7, a salmon fillet 34 is used as the food ingredient to be processed.

The camera 20 captures an image of an unprocessed food ingredient and transmits the captured image to the information processing apparatus 10. The learning unit 111 of the information processing apparatus 10 creates learning input data a by combining each food ingredient captured image before processing and a processing pattern (pattern image) applied to each food ingredient. Each food ingredient captured image before processing is obtained by being divided from the captured images obtained by collectively capturing the respective food ingredients before processing at one angle of view. The learning unit 111 cuts out an image having the same size as the pattern image to obtain each of the food ingredient captured images. Note that the learning unit 111 cuts out a region to which cooking processing is applied (a processing pattern is burned) among the regions of each food ingredient.

Next, cooking processing (laser processing) of burning each processing pattern with laser by the laser processing machine 24 is performed on the salmon fillet 34, and the cooking processing result 42 is imaged by the camera 20. In laser processing of salmon, a laser absorption reaction differs between a red meat portion and a stripe (white striped portion) of salmon, and for example, only the red meat portion changes in color and the stripe remains as it is, so that the processing pattern is interrupted by the stripe, or the processing pattern becomes difficult to understand depending on the position and thickness of the stripe.

Next, the learning unit 111 of the information processing apparatus 10 creates learning input data b by combining each of the food ingredient captured images before processing and each of the food ingredient captured images after processing. Each food ingredient captured image after processing is obtained by being divided from the captured image obtained by capturing the cooking processing result 42. The learning unit 111 cuts out a region to which cooking processing has been applied (a processing pattern is burned) in the region of each food ingredient at the same size as the pattern image to obtain each food ingredient captured image.

Then, the learning unit 111 learns the relationship between the learning input data a and the learning input data b and generates a processing prediction model (second processing prediction model).

### (Operation Processing)

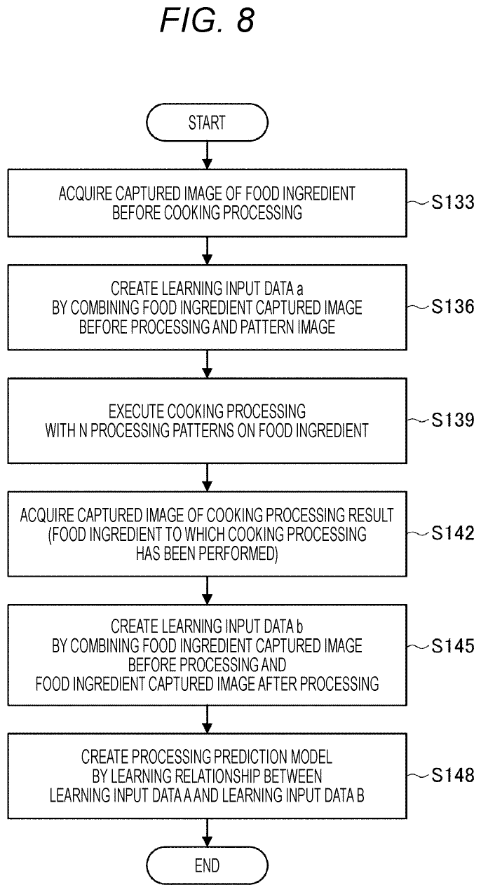

FIG. 8 is a flowchart illustrating an example of a flow of generation processing of the second processing prediction model according to the present embodiment.

As illustrated in FIG. 8, first, the information processing apparatus 10 acquires a captured image of a food ingredient before cooking processing from the camera 20 (step S133). The imaging operation of the camera 20 may be manually performed by the user or may be performed by the information processing apparatus 10.

Next, the learning unit 111 of the information processing apparatus 10 creates learning input data a by combining the captured image of the food ingredient before being processed and the pattern image (step S136).

Next, the control unit 110 of the information processing apparatus 10 performs cooking processing with N processing patterns on the food ingredient by the digital fabrication device (step S139).

Next, the control unit 110 acquires the captured image of the cooking processing result (the food ingredient for which the cooking processing has been performed) from the camera 20 (step S142).

Next, the learning unit 111 of the information processing apparatus 10 creates the learning input data b by combining each food ingredient captured image before processing and each food ingredient captured image after processing (step S145).

Then, the learning unit 111 creates a processing prediction model (second processing prediction model) by learning the relationship between the learning input data a and the learning input data b (step S148). The learning unit 111 can create such a processing prediction model for each food ingredient. In addition, the created processing prediction model is stored in the storage unit 150.

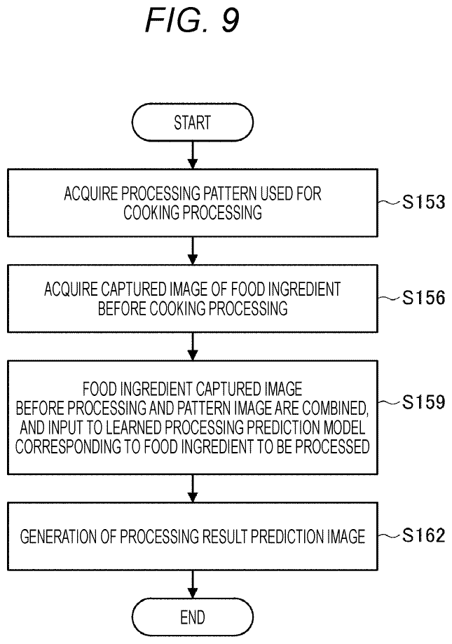

FIG. 9 is a flowchart illustrating an example of a flow of prediction (image generation) processing using the second processing prediction model of the present embodiment.

As illustrated in FIG. 9, first, the cooking processing result prediction unit 112 of the information processing apparatus 10 acquires a processing pattern used for cooking processing (step S153). The processing pattern used for cooking processing is designated by the user from, for example, an operation screen displayed on the display unit 140 of the information processing apparatus 10.

Next, the cooking processing result prediction unit 112 acquires the captured image of the food ingredient before cooking processing from the camera 20 (step S156).

Next, when the food ingredient captured image before processing and the pattern image of the acquired processing pattern described above are combined and input to the learned processing prediction model (second processing prediction model) corresponding to the food ingredient to be processed (step S159), the cooking processing result prediction unit 112 outputs the processing result prediction image from the learned processing prediction model (step S162). In this manner, the cooking processing result prediction unit 112 can generate the processing result prediction image by using the learned processing prediction model.

### <3-3. Third Processing Prediction Model>

Next, learning of the processing prediction model in consideration of components such as the moisture content and sugar content of the food ingredient will be described. Since food ingredients such as vegetables and fruits have different components such as moisture and sugar content depending on a production area, a brand, a season, or the like even for the same kind of food ingredients, there may be a difference in deformation, moisture outflow amount, and the like during cutting processing, and design adjustment may be required. Even in the case of laser processing, the laser absorption varies depending on the component of the food ingredient, and there is a difference in charring and cutting.

Therefore, the learning unit 111 can generate a more accurate processing prediction model by further learning a relationship between a component such as a moisture content of a food ingredient (an example of data of a food ingredient) and a cooking processing result.

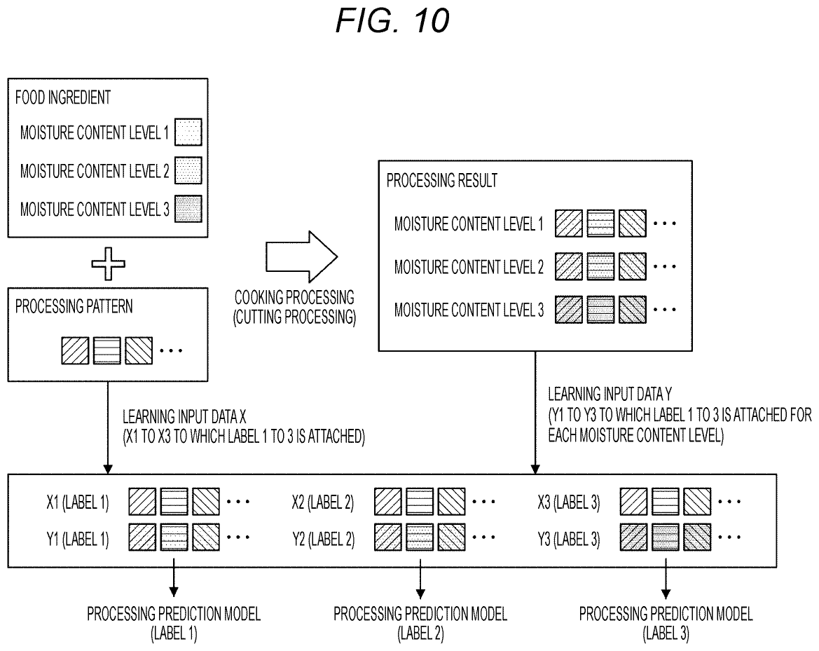

FIG. 10 is a diagram for explaining learning input data used for generating a third processing prediction model according to the present embodiment. The user prepares a food ingredient (for example, a carrot) to be processed and a plurality of different processing patterns. In the present embodiment, as an example, a pattern image used for cutting processing is prepared. Furthermore, the user measures a component of a food ingredient by the food ingredient sensor 22. The food ingredient sensor 22 transmits the sensing data to the information processing apparatus 10. The learning unit 111 of the information processing apparatus 10 determines the component level on the basis of the sensing data acquired from the food ingredient sensor 22.

In the example illustrated in FIG. 10, the moisture content is measured as an example of the component. The information processing apparatus 10 determines the moisture content level of the food ingredient on the basis of the sensing data acquired from the food ingredient sensor 22. Specifically, the information processing apparatus 10 determines which of the levels 1 to 3 the value of the moisture content corresponds to. The value range of the moisture content corresponding to each level may be preset. Note that the range of the value of the moisture content at each level and the number of levels are not particularly limited.

Next, cooking processing of cutting each processing pattern by the cutting processing machine 28 is performed on the food ingredient, and a cooking processing result (cut food ingredient) is imaged by the camera 20. For example, a plurality of food ingredients having the moisture content level 1 is arranged and cut in different processing patterns, and the camera 20 captures an image of the entire plurality of food ingredients from above. Alternatively, each region of the food ingredient having the moisture content level 1 is cut in different processing patterns, and the camera 20 images the entire food ingredient from above. The captured image is transmitted to the information processing apparatus 10.

The learning unit 111 of the information processing apparatus 10 creates learning input data X (for example, a pattern image of a predetermined size) from each processing pattern. The learning unit 111 assigns a label 1 to 3 to the learning input data X, and creates the learning input data X1 of the label 1, the learning input data X2 of the label 2, and the learning input data X3 of the label 3.

In addition, the learning unit 111 creates learning input data Y (cooking processing result image corresponding to each processing pattern, having the same size as the pattern image) from the captured image obtained by capturing the cooking processing result. Specifically, in the case of a captured image obtained by imaging the cooking processing result of the food ingredient of the moisture content level 1, the learning unit 111 creates the learning input data Y1 to which the label 1 is attached. In addition, the learning unit 111 creates the learning input data Y2 to which the label 2 is attached in the case of the captured image obtained by capturing the cooking processing result of the food ingredient at the moisture content level 2, and creates the learning input data Y3 to which the label 3 is attached in the case of the captured image obtained by capturing the cooking processing result of the food ingredient at the moisture content level 3.

Then, the learning unit 111 learns the relationship between the learning input data X (pattern image) and the learning input data Y (cooking processing result image) and generates a processing prediction model (third processing prediction model). The learning unit 111 generates such a processing prediction model for each label. That is, as illustrated in the lower part of FIG. 10, the learning unit 111 learns the relationship between the learning input data X1 (pattern image) and the learning input data Y1 (cooking processing result image of food ingredient of moisture content level 1), and generates the processing prediction model of the label 1 (third processing prediction model corresponding to food ingredient of moisture content level 1). In addition, similarly, the learning unit 111 learns the relationship between the learning input data X2 (pattern image) and the learning input data Y2 (cooking processing result image of food ingredient of moisture content level 2), and generates a processing prediction model of the label 2 (third processing prediction model corresponding to food ingredient of moisture content level 2). In addition, similarly, the learning unit 111 learns the relationship between the learning input data X3 (pattern image) and the learning input data Y3 (cooking processing result image of food ingredient of moisture content level 3), and generates the processing prediction model of the label 3 (third processing prediction model corresponding to food ingredient of moisture content level 3).

### (Operation Processing)

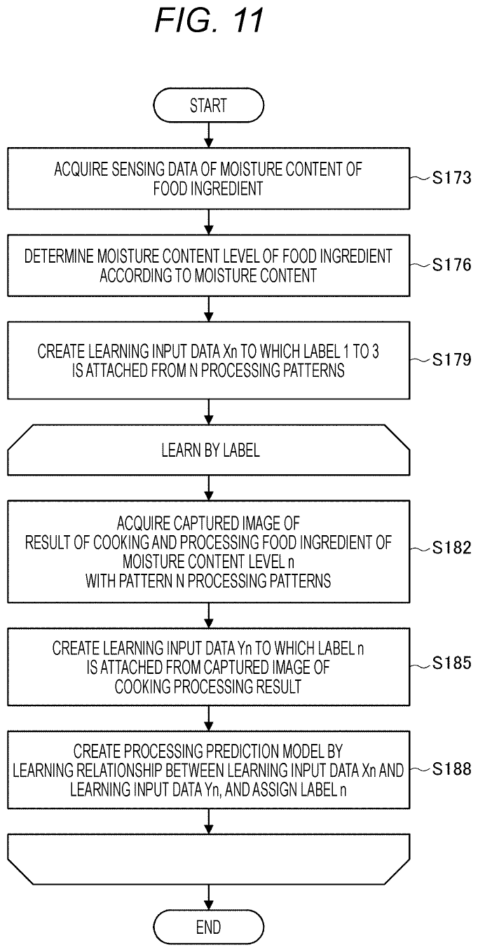

FIG. 11 is a flowchart illustrating an example of a flow of generation processing of a third processing prediction model according to the present embodiment.

As illustrated in FIG. 11, first, the information processing apparatus 10 acquires the sensing data of the moisture content of the food ingredient from the food ingredient sensor 22 (step S173).

Next, the learning unit 111 of the information processing apparatus 10 determines the moisture content level of the food ingredient according to the moisture content indicated by the sensing data (step S176). There is a case where the moisture content level is different even in the same kind of food ingredient, and the user prepares a plurality of the same kind of food ingredients and measures the moisture content level of each food ingredient by the food ingredient sensor 22. In addition, the user prepares a plurality of same types of food ingredients having different moisture content levels for generation of the learning input data with reference to the measurement result by the food ingredient sensor 22.

Next, the learning unit 111 creates learning input data Xn to which the label 1 to 3 is assigned from the N processing patterns (step S179).

Next, the learning unit 111 creates a processing prediction model by performing learning for each label (steps S182 to S188).

Specifically, the learning unit 111 acquires a captured image as a result of cooking and processing the food ingredient with the moisture content level n with the N processing patterns (step S182), and creates the learning input data Yn to which the label n is assigned from the captured image (step S185).

Then, the learning unit 111 creates a processing prediction model by learning the relationship between the learning input data Xn and the learning input data Yn, and assigns a label n (step S188). The learning unit 111 can create the processing prediction model according to the food ingredient component such as the moisture content for each food ingredient. In addition, the created processing prediction model is stored in the storage unit 150.

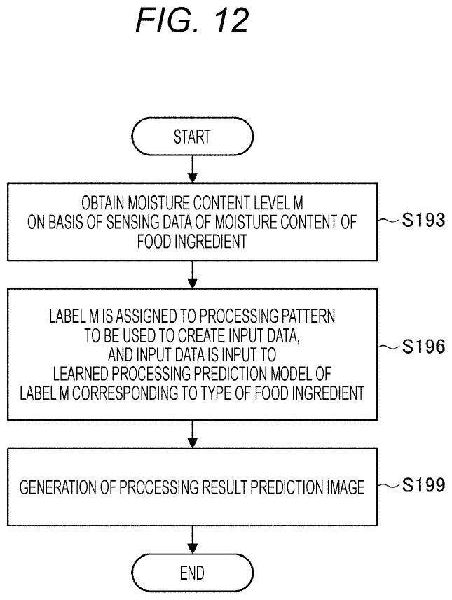

FIG. 12 is a flowchart illustrating an example of a flow of prediction (image generation) processing using the third processing prediction model of the present embodiment.

As illustrated in FIG. 12, first, the cooking processing result prediction unit 112 of the information processing apparatus 10 obtains the moisture content level M on the basis of the sensing data of the moisture content of the food ingredient to be processed (step S193). For example, the food ingredient sensor 22 measures the moisture content of the food ingredient to be processed prepared by the user, and sensing data obtained by the measurement is transmitted from the food ingredient sensor 22 to the information processing apparatus 10.

Next, when the cooking processing result prediction unit 112 creates input data by assigning the label M to the processing pattern to be used and inputs the input data to the learned processing prediction model of the label M corresponding to the type of the food ingredient (step S196), a processing result prediction image is output from the learned processing prediction model (step S199). In this manner, the cooking processing result prediction unit 112 can generate the processing result prediction image by using the learned processing prediction model.

### <3-4. Utilization Example of Processing Prediction Model>

Next, a utilization example of the processing prediction model according to the present embodiment will be described.

The control unit 110 of the information processing apparatus 10 can generate the processing result prediction image from the food ingredient to be processed and the processing pattern using the processing prediction model and present the processing result prediction image to the user. The function of the control unit 110 may be executed by an application installed in the information processing apparatus 10.

Hereinafter, various utilization examples of the processing prediction model according to the present embodiment will be described with reference to the drawings.

### (3-4-1. First Utilization Example)

As a first utilization example of the processing prediction model, a presentation example of the processing result prediction image will be described. FIG. 13 is a diagram illustrating a presentation example of a processing result prediction image according to the present embodiment.

As illustrated on the left of FIG. 13, the operation screen 200 displayed on the display unit 140 includes a food ingredient data input field, a processing pattern input field, and a display field of a processing result prediction image. In the food ingredient data input field, for example, an option of the input food ingredient name is presented by a pull-down menu method and is selected by the user. Further, the user selects the folder icon 201 displayed on the operation screen 200, and selects a file of a desired processing pattern from the opened folder. As a result, an image of the processing pattern selected by the user is displayed in the processing pattern input field.

The cooking processing result prediction unit 112 performs prediction using the processing prediction model (the first processing prediction model described above) on the basis of the food ingredient and the processing pattern selected by the user, and displays the processing result prediction image as illustrated in an operation screen 210 on the right of FIG. 13. The generation processing of the processing result prediction image is as described with reference to FIG. 6. As a result, the user can intuitively grasp how the food ingredient changes, for example, how the food ingredient browns, how the degree of expansion of the food ingredient and the like become in a case where cooking processing (here, laser processing) is performed on the selected food ingredient with the selected processing pattern. Based on such processing prediction, the user can consider a cooking design utilizing digital fabrication.

### (3-4-2. Second Utilization Example)

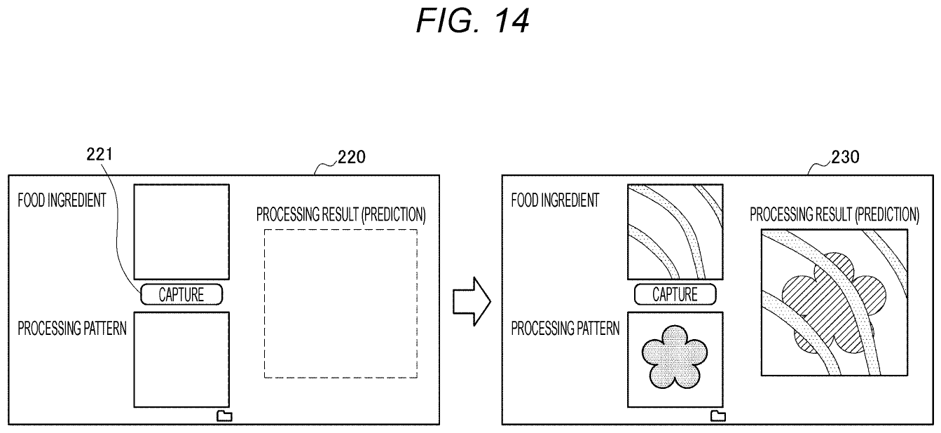

As a second utilization example of the processing prediction model, another presentation example of the processing result prediction image will be described. FIG. 14 is a diagram illustrating another presentation example of the processing result prediction image according to the present embodiment. As illustrated on the left of FIG. 14, the operation screen 220 includes a food ingredient data input field, a processing pattern input field, and a display field of a processing result prediction image. In the example illustrated in FIG. 14, it is possible to capture an image of an unprocessed food ingredient with the camera 20 by selecting the capture button 221 and input the captured image as food ingredient data. For example, for a food ingredient having individual differences that may affect the result of cooking processing, such as stripes of salmon, it is preferable to perform processing prediction using a captured image obtained by capturing an image of the food ingredient to be actually processed. The method of selecting the processing pattern to be input is the same as the example described with reference to FIG. 13.

The cooking processing result prediction unit 112 performs prediction using the processing prediction model (the above-described second processing prediction model) on the basis of the food ingredient captured image before processing and the processing pattern, and displays the processing result prediction image as illustrated in an operation screen 230 on the right of FIG. 14. The generation processing of the processing result prediction image in consideration of the food ingredient captured image before processing is as described with reference to FIG. 9. As a result, the user can intuitively grasp how the prepared food ingredient changes when cooking processing (here, laser processing) is performed on the food ingredient with the selected processing pattern. For example, in the case of salmon, the user can intuitively grasp a change in color and the like of a red meat portion and a stripe portion (white fibrous portion) due to a laser reaction. Based on such processing prediction, the user can consider a cooking design utilizing digital fabrication.

### (3-4-3. Third Utilization Example)

As a third utilization example of the processing prediction model, a presentation example of the processing pattern prediction image will be described. The processing prediction model according to the present embodiment learns the relationship between the learning input data generated from the processing pattern and the learning input data generated from the captured image obtained by capturing the processing result. Therefore, the information processing apparatus 10 can also predict the processing pattern for obtaining the processing result according to the input of the image of the target processing result by the processing pattern prediction unit 113.

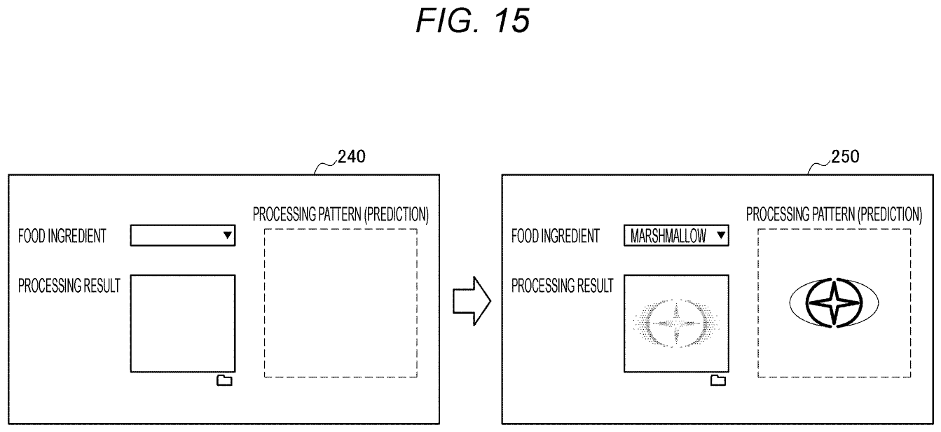

FIG. 15 is a diagram illustrating a presentation example of a processing pattern prediction image according to the present embodiment. As illustrated on the left of FIG. 15, the operation screen 240 includes a food ingredient data input field, a processing result input field, and a display field of a processing pattern prediction image. The user inputs an image of a target processing result in the processing result input field. The image of the target processing result may be, for example, an image in which a user draws a target bulge or burnt color using image creation software.

The processing pattern prediction unit 113 performs prediction using the processing prediction model (the first processing prediction model described above) on the basis of the image of the food ingredient and the processing result selected by the user, and displays the processing pattern prediction image as illustrated in the operation screen 250 on the right of FIG. 15. For example, in a portion where scorching or bulging is strongly expressed in the image of the target processing result, the color of the line of the processing pattern is dark and thick in the processing pattern prediction image. In this way, the user can acquire the processing pattern for obtaining the target processing result, and can perform the cooking design more according to the user's intention.

### (3-4-4. Fourth Utilization Example)

As a fourth utilization example of the processing prediction model, another presentation example of the processing result prediction image will be described. In the present embodiment, the processing prediction corresponding to the moisture content of the food ingredient or the like can be performed by the processing prediction model (the above-described third processing prediction model) learned in consideration of the food ingredient component such as the moisture content of the food ingredient.

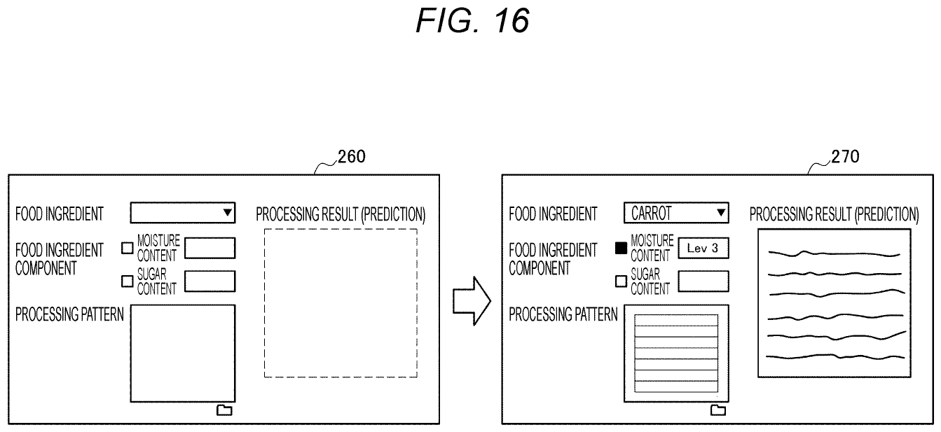

FIG. 16 is a diagram illustrating another presentation example of the processing result prediction image according to the present embodiment. As illustrated on the left of FIG. 16, the operation screen 260 includes a food ingredient data input field, a food ingredient component data input field, a processing pattern input field, and a display field of a processing result prediction image. The user selects a food ingredient and further selects a component to be used for prediction. Here, a case where a carrot is selected as the food ingredient and the moisture content is selected as the component will be described. The user prepares a carrot to be actually processed, and the moisture content of the carrot is measured by the food ingredient sensor 22. The measured value of the moisture content (sensing data) is transmitted from the food ingredient sensor 22 to the information processing apparatus 10.

The cooking processing result prediction unit 112 determines the moisture content level of the food ingredient, similarly to the time of learning. The cooking processing result prediction unit 112 performs prediction using the processing prediction model (the above-described third processing prediction model) on the basis of the food ingredient selected by the user, the moisture content level of the food ingredient, and the processing pattern, and displays the processing result prediction image as illustrated in the operation screen 270 on the right in FIG. 16. The generation processing of the processing result prediction image in consideration of the moisture content level is as described with reference to FIG. 12. As a result, the user can intuitively grasp how the prepared food ingredient changes in a case where cooking processing (here, cutting processing) is performed on the food ingredient with the selected processing pattern. Based on such processing prediction, the user can consider a cooking design utilizing digital fabrication.

### <3-5. Others>

### (Processing Prediction Considering Parameters at Time of Cooking Processing)

The learning unit 111 may learn the relationship with the processing result by using the parameter at the time of cooking and processing of each food ingredient as a label. The parameters at the time of cooking processing are, for example, power and speed of laser output in the case of laser processing.

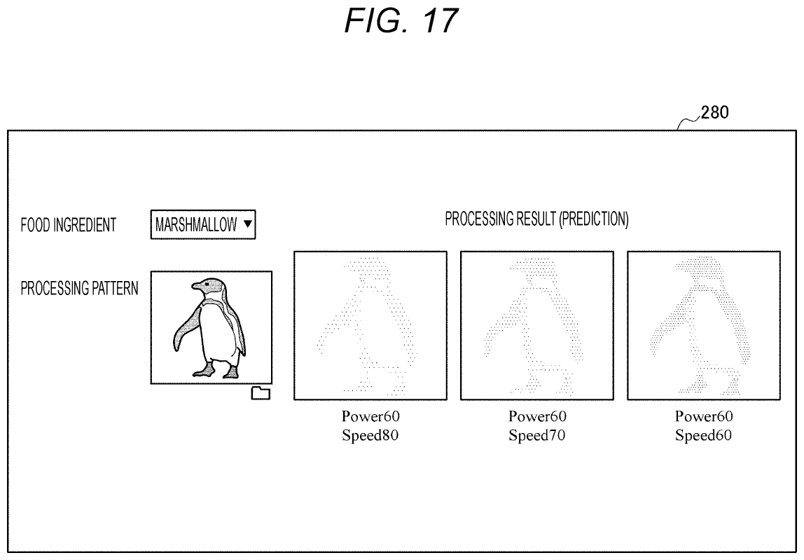

The cooking processing result prediction unit 112 can perform processing prediction for each parameter at the time of cooking processing by using the processing prediction model generated by the above learning. FIG. 17 is a diagram illustrating a presentation example of a processing result prediction image for each parameter at the time of cooking processing according to the present embodiment. As illustrated in an operation screen 280 of FIG. 17, when the user selects a food ingredient and a processing pattern, a processing result prediction image for each parameter at the time of cooking processing is presented as illustrated on the right side of the operation screen 280. As a result, the user can intuitively grasp how the food ingredients swell, burn, and the like become due to the difference in power, speed, and the like of the laser output.

### (Processing Prediction in Case of Layer Structure)

In the present embodiment, it is also possible to predict a result of cooking processing for a more complicated food ingredient, for example, a food ingredient having a layer structure.

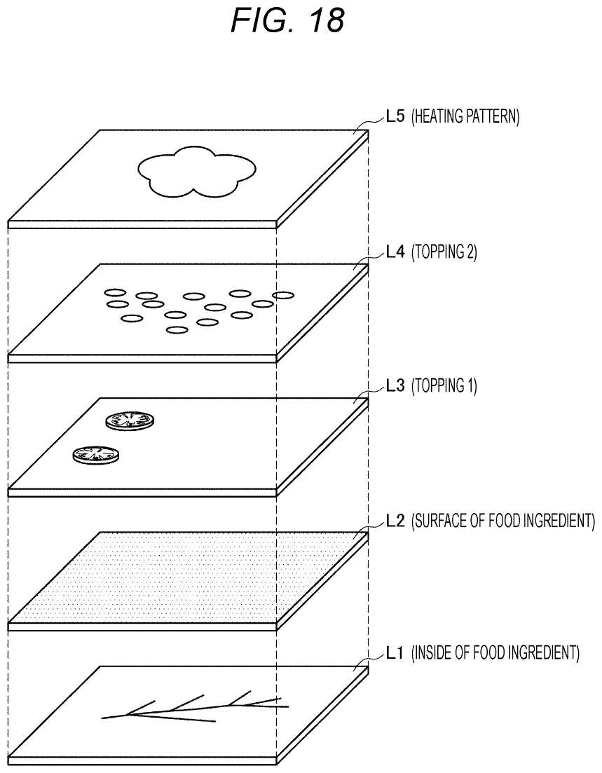

FIG. 18 is a diagram for explaining a food ingredient having a layer structure according to the present embodiment. In the example illustrated in FIG. 18, a case is assumed in which a plurality of toppings is arranged on the surface of a food ingredient having muscles, bones, or the like therein, such as meat or fish, and cooking processing is further performed according to a processing pattern. In this case, as illustrated in FIG. 18, a layer structure of first layer L1: inside of food ingredient, second layer L2: surface of food ingredient, third layer L3: topping 1, fourth layer L4: topping 2, and fifth layer L5: heating pattern is formed.

The layer structure is common in conventional dishes such as pizza, but a precise cooking design can be made by using digital fabrication processing. Here, in the case of a food ingredient (dish) having a layer structure, the processing result may locally change depending on the internal structure of the food ingredient and the arrangement of the topping. Therefore, in the present embodiment, a processing prediction model that has learned the relationship with the layer structure is generated, and the result of cooking processing on the food ingredient having the layer structure can be predicted. As a result, the user can consider a cooking design utilizing digital fabrication for a food ingredient (dish) having a layer structure.

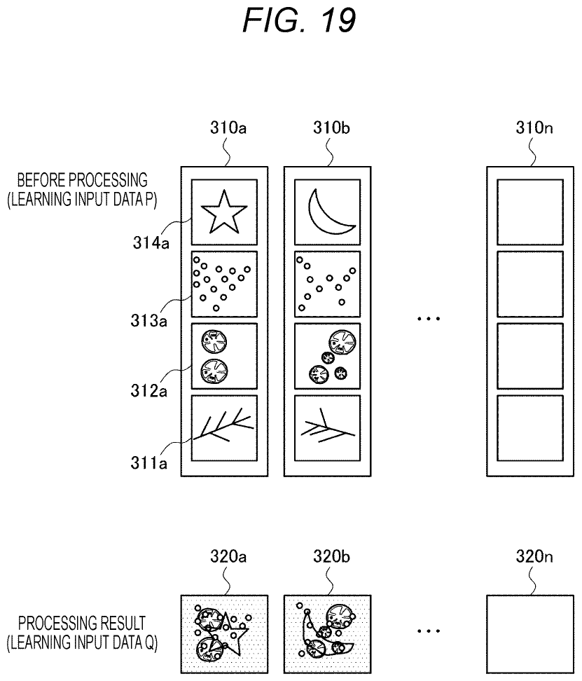

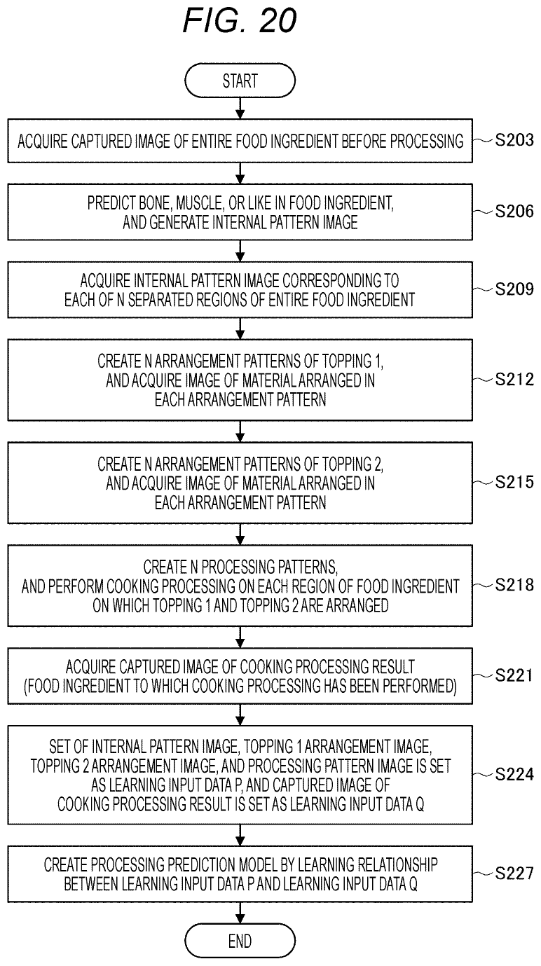

Next, a learning example of the processing prediction model corresponding to the layer structure will be described with reference to FIGS. 19 and 20. FIG. 19 is a diagram for explaining learning input data used for generating a processing prediction model corresponding to a layer structure according to the present embodiment. As illustrated in FIG. 19, in the present embodiment, a set of images (combinations 310a to 310n) of each layer before processing is set as learning input data P, and captured images 320a to 320n of cooking processing results are set as learning input data Q. The set of images of each layer before processing includes, for example, an internal pattern image 311 of the food ingredient, an image of the first topping (topping arrangement image) 312 to be arranged on the food ingredient, an image of the second topping (topping arrangement image) 313 to be arranged on the food ingredient, and a processing pattern image 314.

FIG. 20 is a flowchart illustrating an example of a flow of generation processing of a processing prediction model corresponding to a layer structure according to the present embodiment.

As illustrated in FIG. 20, first, the information processing apparatus 10 acquires a captured image of the entire food ingredient before cooking processing from the camera 20 (step S203). For example, imaging of a food ingredient having a bone, a muscle, or the like inside, such as fish or chicken, is assumed. The imaging operation of the camera 20 may be manually performed by the user or may be performed by the information processing apparatus 10.

Next, the learning unit 111 of the information processing apparatus 10 predicts a state (position, shape, or the like) of a bone, a muscle, or the like inside the food ingredient from the captured image of the entire food ingredient, and generates an internal pattern image of the entire food ingredient (step S206). The prediction of the internal state may be performed using a model learned in advance using an internal image acquired by computed tomography (CT) or the like. Furthermore, in a case where the internal structure of a 3D-printed food ingredient or the like is known in advance, the learning unit 111 may use data of such an internal structure.

Next, the learning unit 111 acquires an internal pattern image corresponding to each of the N regions obtained by dividing the entire food ingredient (step S209). In the present embodiment, as an example, one food ingredient is divided into a plurality of regions, and each region is cooked and processed with a different processing pattern, and a plurality of data used for learning is efficiently acquired.

Next, the learning unit 111 creates N arrangement patterns of each of the topping 1 and the topping 2, and acquires an image of the material (topping arrangement image) arranged in each arrangement pattern (steps S212 and S215). The learning unit 111 may randomly create each arrangement pattern, or may use an arrangement pattern prepared in advance. The arrangement of each material can be performed precisely by the cooking robot 26.

The learning unit 111 may acquire the topping arrangement image from the captured image obtained by imaging the food ingredient on which the material is topped by the camera 20. The overlap with the lower layer is eliminated by removing the difference in the image processing, and the learning unit 111 can acquire the image of only the corresponding layer. Note that, in a case where it is difficult to recognize the material to be topped from the captured image such as seasoning, the learning unit 111 may use the image of the arrangement pattern as the topping arrangement image, or may generate the topping arrangement image from the information of the arrangement pattern and the material. In a case where the material to be topped is a material having an individual difference that particularly affects the processing result (for example, in a case of materials such as tomato), the learning unit 111 acquires the topping arrangement image from the captured image as described above.

Next, the learning unit 111 creates N processing patterns, and performs cooking processing on each region of the food ingredient on which the topping 1 and the topping 2 are arranged by the laser processing machine 24 (step S218).

Next, the learning unit 111 acquires the captured image of the cooking processing result (food ingredient for which cooking processing has been performed) from the camera 20 (step S221).

Next, the learning unit 111 sets the set of the internal pattern image, the topping 1 arrangement image, the topping 2 arrangement image, and the processing pattern image as the learning input data P, and sets the captured image of the cooking processing result as the learning input data Q (step S224), and learns the relationship between the learning input data P and the learning input data Q to create the processing prediction model (step S227).

The cooking processing result prediction unit 112 predicts the processing result of the food ingredient having the layer structure (generates the processing result prediction image) using the processing prediction model generated in this manner. For example, the user can select a food ingredient, a topping, and a processing pattern from an operation screen (not illustrated), and intuitively grasp a processing result in which the internal structure of the food ingredient and the arrangement of the topping are considered.

### <<4. Presentation of Cooking Design Proposal>>

Next, presentation of a cooking design proposal that satisfies various cooking conditions will be described. The control unit 110 of the information processing apparatus 10 can present a cooking design proposal that satisfies the cooking conditions including at least one of the user's intention, the state of food ingredients, customer restrictions, work restrictions, or the like.

Examples of the intention of the user include design points, concepts, or orientations (specifically, for example, the position of the main food ingredient and a rough sketch), visual effects, ease of eating, a golden ratio, a food ingredient that should be preferentially used, a portion of the food ingredient that should be used, a balance of the amount of the food ingredient, a combination of food ingredients, compatibility between food ingredients, a ratio between food ingredients and a sauce, a change in taste or texture, a material cost (cost), man-hours, a nutritional balance, food loss (food ingredient inventory consumption, or the like), and the like.

Examples of the state of the food ingredient include a time from the start of processing to deterioration or deformation (melting or solidifying) (that is, a processing limit time), a temperature at which the food ingredient deteriorates or deforms, and the like.

Examples of the restriction on the customer who is the recipient of the dish include preference or restriction on the customer's food ingredients (allergy, chewing difficulty, or the like) and texture restriction on the food ingredients related to ease of eating (size, shape, viscosity, or the like).

As the restriction of the work, for example, there are restrictions such as a margin required for an operation path of a device (laser processing machine 24, cutting processing machine 28, and the like) that performs cooking processing or the cooking robot 26, and a thermal influence by cooking processing.

The cooking conditions described above are examples, and the present embodiment is not limited thereto.

The control unit 110 may present a cooking design using digital fabrication processing. Furthermore, the control unit 110 may present a cooking processing result (processing result prediction image) predicted using a learned processing prediction model as a cooking design proposal.

Hereinafter, a presentation example of a cooking design proposal according to the present embodiment will be specifically described.

### <4-1. First Cooking Design Presentation Example>

As a first cooking design presentation example, a design of a topping layout of a cake will be described. The cooking design presentation function according to the present embodiment is also used as a cake topping design tool.

### (1) Arrangement of Main Topping

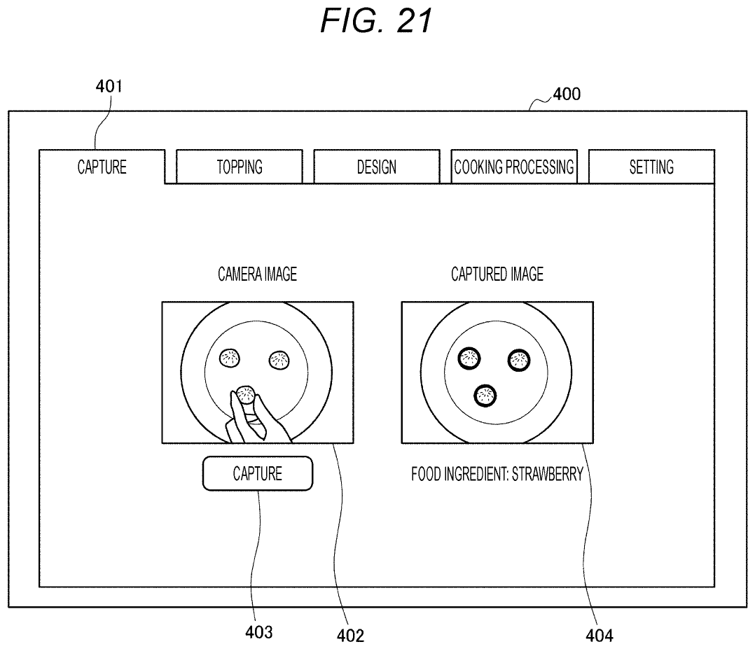

FIG. 21 is a diagram illustrating an example of a capture screen in the design tool screen according to the present embodiment. As illustrated in FIG. 21, the design tool screen 400 has five tabs, and screens of capture, topping, design, cooking processing, and setting can be selected. In the example illustrated in FIG. 21, capture is selected among the five tabs, and the capture screen 401 is displayed.

On the capture screen 401, a through image 402 of the camera 20 (referred to as a “camera image” in FIG. 21) and a captured image 404 (referred to as a “capture image” in FIG. 21) captured in response to selection of the capture button 403 are displayed.

First, a user (for example, chef) arbitrarily places a cake main topping (for example, strawberry) on a dish within the angle of view of the camera 20 as illustrated in FIG. 1, confirms the through image 402, and selects the capture button 403. In the present embodiment, a topping layout (design) on a general circular cake base is assumed as an example. The arrangement of the main topping may be arranged not on a dish but on a cake base and imaged by the camera 20. In this way, the design intention of the user is incorporated.

When the capture button 403 is selected, the captured image 404 captured by the camera 20 is displayed as illustrated in FIG. 21. The cooking design generation unit 116 performs image analysis on the captured image 404, and acquires information of the food ingredient type, the position (arrangement), and the contour of the main topping. For example, the cooking design generation unit 116 inputs the captured image 404 to the learned model of the food ingredient image to recognize the food ingredient type. In addition, the cooking design generation unit 116 also performs image analysis on the captured image 404 to detect the position (arrangement) and contour of the main topping. As illustrated in FIG. 21, a display indicating the contour of the main topping detected by the cooking design generation unit 116 is superimposed on the captured image 404. Furthermore, the cooking design generation unit 116 may further acquire information such as the 3D shape and orientation of the main topping from the captured image.

The user confirms whether the display (that is, arrangement of main topping) indicating the contour of the main topping and the food ingredient type displayed on the capture screen 401 are correct. In a case of doing so again, the user adjusts the position of the main topping on the dish and selects the capture button 403 again. If there is no problem, the user selects the next tab “topping.”

### (2) Selection of Topping

When the “topping” tab is selected from the five tabs displayed on the design tool screen 400, the topping screen is displayed. FIG. 22 is a diagram illustrating an example of a topping screen in the design tool screen according to the present embodiment.

As illustrated in FIG. 22, a list of toppings is displayed on the topping screen 411 in the design tool screen 410. The topping 1 is a main topping, and an image corresponding to the food ingredient name recognized from the captured image 404 described above is displayed. The topping 2 and the topping 3 are sub-toppings used as a sub topping for the main topping (the topping 1). On the topping screen 411, a processing means is displayed above each of the topping lists. The topping 1 is manually placed by a user, the topping 2 is placed by a robot hand of the cooking robot 26, and the topping 3 is engraved by the laser processing machine 24. Note that the processing means is an example, and the present embodiment is not limited thereto.

On the topping screen 411, a plurality of material candidates for the topping 2 is displayed. Material candidates for the topping 2 to be used as a sub can be selected by the material selection unit 114. As material candidates for the topping 2, materials that the user often combines may be predicted from combinations of food ingredients in the user's past dishes, or materials that are frequently used may be selected from analysis of cooking recipe data. The user checks the material candidates for topping 2, and deletes any material that the user does not want to use.

As the topping 3, a processing result prediction image for each processing pattern is displayed. By digital fabrication, it is possible to engrave processing patterns such as various patterns on a cake by, for example, laser processing, and in the present embodiment, such processing is also presented as a sub-topping. The candidate processing pattern is generated by the processing pattern generation unit 115. The processing pattern generation unit 115 predicts a processing pattern frequently used by the user, for example, using a model generated by learning the user's past dishes. For example, in a case where the user uses nature such as a flower or an insect as a motif, a processing pattern like a flower is generated. Furthermore, a geometric pattern or a processing pattern such as an animal may be generated depending on the user's past dish. Next, the cooking processing result prediction unit 112 generates each processing result prediction image in a case where each processing pattern is engraved on the cake using the learned processing prediction model according to the processing pattern generated by the processing pattern generation unit 115 and the processing target (here, a cake), and presents the processing result prediction image as a candidate for the topping 3. The user visually confirms the processing result prediction image of the plurality of processing patterns presented as the topping 3, and deletes any processing pattern that the user does not want to use. If there is no problem, the user selects the next tab “design”.

Note that the user can also add a processing pattern used for the topping 3. The addition method is not particularly limited, but in the present embodiment, when the user selects the plus button 412 displayed on the topping 3 on the topping screen 411, the topping 3 addition screen is popped up.

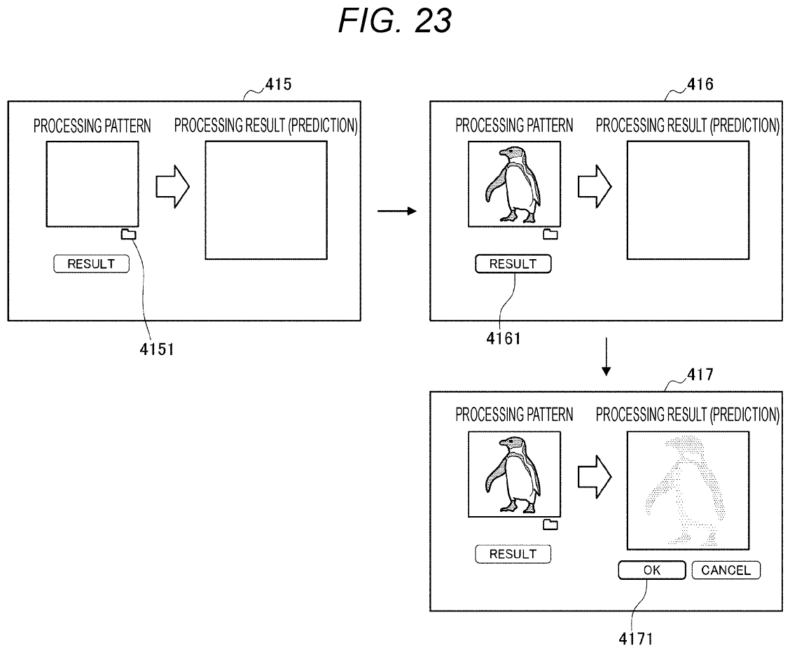

FIG. 23 is a diagram illustrating an example of a topping 3 addition screen according to the present embodiment. As illustrated in the upper left of FIG. 23, the topping 3 addition screen 415 includes a processing pattern input field and a display field of a processing result prediction image. The user selects the folder icon 4151 displayed under the processing pattern input field on the topping 3 addition screen 415, and selects the file of the processing pattern to be added from the opened folder. As a result, as illustrated in the topping 3 addition screen 416 in the upper right of FIG. 23, an image of the processing pattern selected by the user is displayed in the processing pattern input field. Next, when the user selects the RESULT button 4161, the cooking processing result prediction unit 112 inputs the image of the processing pattern selected by the user to the learned processing prediction model to predict the processing result, and displays the processing result prediction image as illustrated in the topping 3 addition screen 417 in the lower right of FIG. 23. In a case of adding the processing result prediction image to the topping 3, the user selects the OK button 4171. As a result, the pop-up display of the topping 3 addition screen 417 ends, and the processing result prediction image described above is added to the list of the topping 3 on the topping screen 411.

### (3) Presentation of Proposed Design

Next, the user selects a tab of “design” among the five tabs displayed on the design tool screen 410. FIG. 24 is a diagram illustrating an example of a topping screen in the design tool screen according to the present embodiment.

As illustrated in FIG. 24, a cooking condition input field 422, a cooking design proposal 423, and a graph 424 indicating the condition matching degree of each cooking design proposal are displayed on a design screen 421 in the design tool screen 420.

The cooking condition input field 422 displayed above the design screen 421 is an area indicating a cooking condition for optimizing the combination of toppings. The “quantity range of each topping” is a range of the quantity of the sub-topping (the topping 2 and the topping 3) that can be changed when the cooking design generation unit 116 generates the cooking design proposal. In the present embodiment, as an example, 0 to 6 of the maximum 10 values of the quantity range are set. The user can set an arbitrary numerical value.

Furthermore, in the cooking condition input field 422, target values of “cost”, “food ingredient priority”, and “customer preference” are illustrated as an example of the cooking condition. The target values of the “cost”, the “food ingredient priority”, and the “customer preference” may be set in advance by the user.

“Cost” is the total cost of all topping. The price of the topping is calculated in cooperation with material price data prepared in advance or a material management list (list of management data such as purchase date, purchase price, and number of materials) of the user. In the example illustrated in FIG. 24, the target value is set to “200 yen” out of the maximum value of 500 yen.

In the “food ingredient priority”, when priority is set in 10 stages in advance for each food ingredient (including materials), a preferable average value of the priorities of the materials used for topping can be set. The priority for each food ingredient may be arbitrarily appropriately set by the user. For example, the user sets the priority of a food ingredient in excess of stock or a food ingredient desired to be used (seasonal food ingredient or the like) to be high. In the example illustrated in FIG. 24, the target value is set to priority 7 out of a maximum priority of 10.

In the “customer preference”, when the customer preference is set in 10 stages in advance for each food ingredient (including materials), a preferable average value of the customer preference of the material used for topping is set. For example, the degree of preference of the customer for each food ingredient is calculated by analyzing an order history of the customer obtained from a customer management list that manages customer information. In the case of the present embodiment, the customer is the recipient of a cake as a cooking design target. The cooking design generation unit 116 can analyze the order history of the cake orderer in the customer management list and set the customer's preference for each food ingredient. Note that the preference information of the customer includes not only likes and dislikes of food ingredients but also use restriction (allergy, illness, or the like) of food ingredients. In the example illustrated in FIG. 24, the target value is set to preference level 8 out of a maximum preference level of 10.

The cooking conditions described above are examples, and the present embodiment is not limited thereto. Furthermore, the cooking condition is not limited to designation by numerical values (target values), and may be designated in a natural language, a schematic diagram, or the like.

At the center of the design screen 421, the cooking design proposal generated by the cooking design generation unit 116 is displayed. Based on the arrangement of the main topping imaged by the camera 20, the cooking design generation unit 116 generates a cooking design by appropriately combining and arranging the topping 2 (material candidate selected by the material selection unit 114) and the topping 3 (processing prediction result image of the processing pattern). Each of the cooking design proposals displayed on the design screen 421 may be a CG image obtained by 3D simulating the topping on the basis of the cooking design. Although the positions of the strawberries manually arranged by the user are common, various combinations of the topping 2 and the topping 3 are tried in the cooking design generation unit 116, and are displayed in the order of optimized combinations satisfying the target value as much as possible. The target value matching degree of each cooking design proposal is indicated by a graph 424 displayed at the bottom of each cooking design proposal.

Here, an example of a method for designing a cake topping by the cooking design generation unit 116 will be described. The cooking design generation unit 116 combines the materials (topping 2: material candidates for sub-topping, topping 3: processing prediction result image of processing pattern) by randomly changing the quantities of the topping 2 and the topping 3 within the range set in the “quantity range of each topping”, and calculates the sum of the costs of the materials in each combination, the average value of the food ingredient priorities, and the average value of the customer preferences. At this time, the cooking design generation unit 116 refers to a food ingredient data list as illustrated in the following Table 1.

TABLE 1

| Food ingredient | | Food ingredient | Customer |
|---|---|---|---|
| (material) | Cost | priority | preference |
| Blueberry | 7.24 | 4 | 3 |
| Muscat | 32.4 | 8 | 6 |
| Raspberry | 20.53 | 4 | 8 |
| . . . | | | |
| Flower pattern 1 | 0.53 | 8 | 7 |

Next, the cooking design generation unit 116 obtains each difference between the target values of the three cooking conditions such as “cost”, “food ingredient priority”, and “customer preference” and the sum of the costs of the materials in each combination, the average value of the food ingredient priorities, and the average value of the customer preference, and lists the combinations in order from the combination that satisfies the three target values most.

Next, the cooking design generation unit 116 selects the top three sets in the list. Note that, here, three sets are selected as an example, but how many sets are selected is not particularly limited. On the basis of the information on the position and the contour of the main topping recognized from the captured image captured by the camera 20, the cooking design generation unit 116 arranges the 3D model of strawberry on the cake of the 3D model in accordance with the coordinate system and scale of the cake to be simulated. Next, the cooking design generation unit 116 refers to the contour size list of each topping as illustrated in Table 2 below, and calculates the diameter of a circle obtained by adding the range of the device operation margin and the like at the time of cooking processing as illustrated in Table 3 below to the contour size of each topping. The range of the contour size of each topping, the device operation margin at the time of cooking processing, and the like is set in advance on the setting screen.

TABLE 2

| Food ingredient | Contour |
|---|---|
| (material) | (radius) |
| Blueberry | 4.21 |
| Muscat | 13.1 |
| Raspberry | 10.82 |
| . . . | |
| Flower pattern 1 | 9.0 |

TABLE 3

| Cooking processing | Margin |
|---|---|
| Cooking robot | 13.2 |
| Laser processing | 5.21 |
| machine | |
| . . . | |

For example, in the case of the blueberry arranged by the cooking robot 26, the contour radius at the time of layout is 17.41 mm obtained by adding the end part operation margin of the robot hand of 13.2 mm to the food ingredient radius of 4.21 mm. In addition, the margin of the laser processing machine takes into consideration the thermal influence at the time of processing. For example, when a pattern is engraved with a laser, the laser is absorbed by the food ingredient to generate heat, and the heat propagates inside the material. For this reason, the topping (jelly, chocolate, or the like) melted by heat needs to be arranged at a distance not affected by heat propagation. In the present embodiment, the layout can be performed in consideration of the thermal influence by defining the heat propagation region as a margin. Note that, in the present embodiment, a margin is uniformly added including a material that does not melt with heat, but the margin may be individually set in consideration of the characteristics of the material. Furthermore, since the laser reaction differs depending on the moisture content of the food ingredient and the thermal influence also changes, the cooking design generation unit 116 may adjust the margin according to the measurement result by the food ingredient sensor 22.

Next, for each of the top three sets of the list, the cooking design generation unit 116 arranges the 3D model of each topping on the cake by the plane filling algorithm in consideration of the diameter of the circle obtained by adding a margin to the contour size. As a result, three topping layouts (cooking design proposals) are generated.

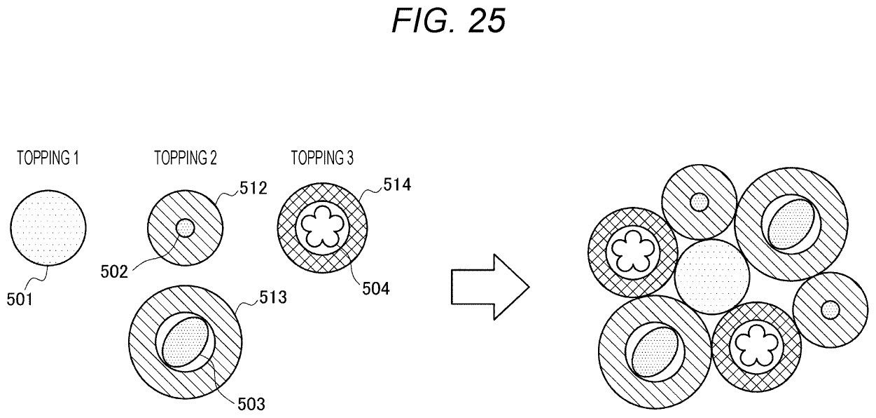

FIG. 25 is a diagram for explaining arrangement in consideration of margins of each topping according to the present embodiment. When arranging each topping, as illustrated on the left side of FIG. 25, the cooking design generation unit 116 recognizes the contour of the main topping 501 as the topping 1, a circle obtained by adding a margin 512 to the contour size of the sub-topping 502 as the topping 2, a circle obtained by adding a margin 513 to the contour size of the sub-topping 503, and a circle obtained by adding a margin 514 to the contour size of the processing pattern 504 of the topping 3, and then, as illustrated on the right side of FIG. 25, arranges the respective regions so as not to overlap each other. As a result, in the present embodiment, it is possible to realize the arrangement in consideration of the device operation margin (including the range of thermal influence) at the time of cooking processing.

Although the cooking design generation unit 116 arranges (layout, that is, generation of a cooking design proposal) each topping on the cake using a plane filling algorithm as an example, the present embodiment is not limited thereto, and other algorithms may be used. Furthermore, the cooking design generation unit 116 may arrange each topping using artificial intelligence (AI). Furthermore, the cooking design generation unit 116 may arrange each topping in consideration of user's intention such as a point or orientation of a design input in a numerical value, a natural language, a schematic diagram, or the like.

As described above, the cooking design generation unit 116 performs simulation of the topping layout using the 3D models corresponding to the respective toppings of the top three sets in the list, and displays the simulation result (cooking design proposal) on the design screen 421 as a 2D image or a 3D image. The user can visually grasp each topping layout (that is, an optimized cooking design proposal) using the top three sets of topping materials that meet the three target values. The cooking design generation unit 116 stores the topping layout selected by the user in the storage unit 150.

Note that, in the present embodiment, the topping layout on a general circular cake base is performed, but the user may select the shape of the cake such as a square, a rectangle, or an ellipse. Furthermore, the information processing apparatus 10 may capture the shape of the cake base as a 3D model on the basis of the captured image obtained by imaging the actual cake base with the camera 20, and perform the topping layout on the basis of the captured 3D model of the cake base.

Furthermore, in the above-described embodiment, imaging of the main topping has been described as a method of incorporating the design intention of the user, but the present embodiment is not limited thereto. For example, the cooking design generation unit 116 may perform a layout in which the main topping is arranged along a line drawn by the user and the sub-topping is scattered around the main topping. Furthermore, the cooking design generation unit 116 may perform layout such as dividing the region on the basis of the figure drawn by the user and dividing the topping between the inside and the outside of the figure.

Furthermore, an example in which the user sets in advance the food ingredient priority, the customer preference, and the like as the cooking conditions for the design optimization has been described, but the present invention is not limited thereto, and the cooking design generation unit 116 may automatically calculate the cooking conditions from trends and past cases. Furthermore, the cooking design generation unit 116 may set a target of the processing restriction time in a case where it is necessary to prevent food ingredient deterioration such as fresh food, and adjust the type or number of toppings such that the total processing time of the cooking robot or the processing machine for each topping falls within the target time.

### (4) Cooking Processing Control

Next, the user selects the tab of “cooking processing” among the five tabs displayed on the design tool screen 420. On the cooking processing screen (not illustrated) displayed by selecting the tab of “cooking processing”, for example, a message to perform cooking processing on the basis of the cooking design selected by the user on the design screen 421, a message to instruct the user to prepare a cake base or the like, an execution button, and the like are displayed. When the execution button is selected, the device cooperation unit 117 transmits information on cooking processing to the digital fabrication device on the basis of the cooking design selected by the user. For example, the device cooperation unit 117 transmits data of the type and position of the topping to be placed to the cooking robot 26, and transmits data of the type and position of the processing pattern to the laser processing machine 24 or the cutting processing machine 28. Note that the device cooperation unit 117 may directly control at least one of the cooking robot 26, the laser processing machine 24, or the cutting processing machine 28.

### (5) Setting

When the “setting” tab is selected from the five tabs displayed on the design tool screen 420, a setting screen is displayed. On a setting screen (not illustrated), general settings such as language, availability of cooking conditions such as cost, food ingredient priority, and customer preference, a target value, designation of a data file to cooperate, a margin value of cooking processing, and the like are set.

### (6) Operation Processing

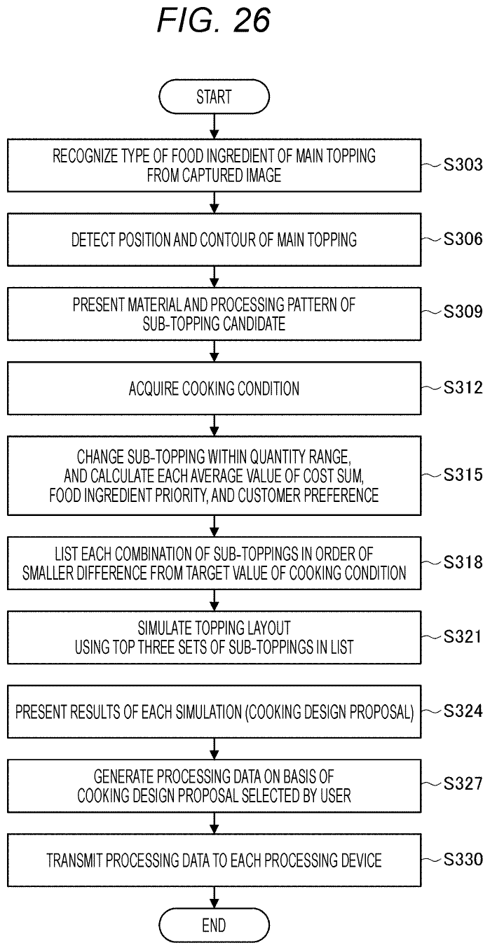

Next, operation processing of the cooking design according to the present embodiment will be described with reference to FIG. 26. FIG. 26 is a flowchart illustrating operation processing of the cooking design (layout of cake topping) according to the present embodiment.

As illustrated in FIG. 26, first, the cooking design generation unit 116 of the information processing apparatus 10 recognizes the food ingredient type of the main topping on the basis of the captured image captured by the camera 20 (step S303). The cooking design generation unit 116 inputs the captured image to the learned model of the food ingredient image and recognizes the food ingredient type. The captured image and the recognition result are displayed on the display unit 140 (see FIG. 21).

Next, the cooking design generation unit 116 analyzes the captured image, and detects the position and contour of the main topping (step S306). The detection result of the position and the contour of the main topping is superimposed on the captured image displayed on the display unit 140 (see FIG. 21).

Next, the material (topping 2) selected according to the main topping by the material selection unit 114 and the processing prediction result image (topping 3) of the processing pattern generated by the processing pattern generation unit 115 are presented (see FIG. 22) (step S309).

Next, the cooking design generation unit 116 acquires cooking conditions (step S312). As described above, the cooking conditions include “quantity range of each topping”, “cost”, “food ingredient priority”, and “customer preference” (see FIG. 24). The cooking condition may be set in advance by the user from the setting screen.

Next, the cooking design generation unit 116 changes and combines the sub-topping (topping 2 and topping 3) within the quantity range, and obtains a sum of costs of each combination, an average value of food ingredient priorities, and an average value of customer preferences (step S315).

Next, the cooking design generation unit 116 lists each combination of the sub-topping in ascending order of differences from the target values of the three conditions of “cost”, “food ingredient priority”, and “customer preference”, and obtains a suitable combination (step S318). In the present embodiment, the top three sets in the list are suitable combinations. As an algorithm for obtaining a suitable combination, a genetic algorithm or the like may be used in addition to the exhaustive search.

Next, the cooking design generation unit 116 simulates the topping layout using the top three sets of sub-topping in the list (step S321). Details of the simulation of the topping layout are as described above.

Next, the cooking design generation unit 116 presents a result of each simulation (for example, a cooking design proposal such as an image of a cake on which topping layout is performed using a 3D model) (see FIG. 24) (step S324).

Next, the device cooperation unit 117 generates processing data (data of the type and position of the topping to be arranged, and data of the type and position of the processing pattern) on the basis of the cooking design proposal selected by the user (step S327), and transmits the processing data to each processing device (cooking robot 26, laser processing machine 24, and cutting processing machine 28) (step S330).

### <4-2. Second Cooking Design Presentation Example>

Next, a design example of a salad plate on which a large number of vegetables are arranged will be described. It is conceivable to design a salad plate by applying one of patterns seen in nature, such as a Voronoi pattern, to vegetables by cutting processing by digital fabrication processing. The cooking design generation unit 116 can also design the texture of the vegetable by appropriately adjusting the Voronoi pattern according to the intention of the user or the preference or restriction of the customer.

### (1) Design Creation Screen

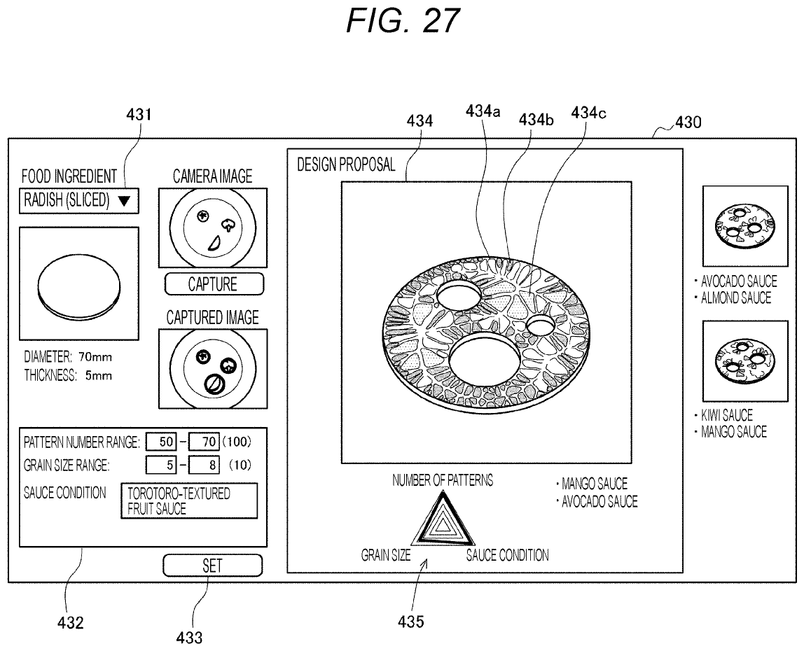

FIG. 27 is a diagram illustrating an example of a design creation screen of a salad plate according to the present embodiment. First, the user selects a base food ingredient in a food ingredient selection field 431 illustrated on the left side of the design creation screen 430 illustrated in FIG. 27. In the example illustrated in FIG. 27, sliced radish is selected. The food ingredient and the shape of the food ingredient that can be selected in the food ingredient selection field 431 can be set in advance. Furthermore, the size of the food ingredient may be arbitrarily set by the user.

A through image of the camera 20 (“camera image” in FIG. 27) and a captured image captured by the camera 20 by selection of the capture button (“capture image” in FIG. 27) are displayed next to the food ingredient selection field 431. The user arranges the auxiliary food ingredients to be served on the base food ingredient (for example, sliced radish) in the salad plate on the plate, places the auxiliary food ingredients within the angle of view of the camera 20, and captures an image. The cooking design generation unit 116 analyzes the captured image, and detects the position and contour of each auxiliary food ingredient. In the present embodiment, in the slice of radish as the base food ingredient, a design is provided in which a portion corresponding to the position and contour of each auxiliary food ingredient is cut into a circle. This is because each of the captured auxiliary food ingredients is arranged in or under the circle at the time of serving. Furthermore, in the slice of radish as the base food ingredient, a design for cutting an arbitrary portion may be provided for decoration.

A condition setting field 432 for setting cooking conditions for optimizing the Voronoi pattern is displayed below the food ingredient selection field 431. In the present embodiment, the Voronoi pattern is divided into three groups, which are regions of vegetable grains, sauce 1, and sauce 2. The sauce is generally poured from above, but in the present embodiment, a film is designed to be formed in holes of a Voronoi pattern by the viscosity of the sauce. Therefore, it is assumed that a preferable size of the hole according to the sauce viscosity is obtained in advance by an experiment or the like and data is prepared. In addition, holes to be filled with sauce are processed with a parameter of strength that completely cuts through, while the grain portions are not cut through but are incised with a parameter of strength such that they separate by chewing.

In the “pattern number range” in the condition setting field 432, a target value of the number of Voronoi patterns is set. In the present embodiment, for example, the value is set to between 50 and 70 out of a maximum value of 100. The “grain size range” is set to between 5 mm and 8 mm out of a maximum value of 10 mm, for example. For example, in the case of a customer with swallowing disorder such as an elderly person, the user can set the grain size according to the state of the customer.

In the “sauce condition”, the user can input the taste, texture, or the like of the sauce in natural language.

Then, when the user selects the set button 433 displayed below the condition setting field 432, the cooking design generation unit 116 simulates the layout (layout of the Voronoi pattern) and the sauce type that satisfy the condition set in the condition setting field 432 as much as possible, and displays the result (image 434 of the cooking design proposal) on the design creation screen 430. Note that the rightmost column of the design creation screen 430 is the previous cooking design proposal. In addition, under the image 434 of the cooking design proposal, a graph 435 indicating the matching degree with the cooking conditions (conditions set in the condition setting field 432) in the presented cooking design proposal is displayed.

As described above, the user designates the user's intention such as the type of the base food ingredient and the arrangement of the auxiliary food ingredient, and further sets the cooking conditions such as the number of processing patterns (here, the Voronoi pattern) and the sauce conditions, whereby a suitable cooking design proposal (specifically, a design of a Voronoi pattern applied to the base food ingredient) of the salad plate can be acquired. Since the cooking design proposal is presented by the image in which the design of the Voronoi pattern is applied to the 3D model in which the base food ingredient is simplified, the user can intuitively grasp the cooking design proposal. In the image 434 of the cooking design proposal displayed on the design creation screen 430 of FIG. 27, a grain region 434a, a region 434b of the sauce 1, and a region 434c of the sauce 2 are arranged in the base food ingredient.

### (2) Operation Processing

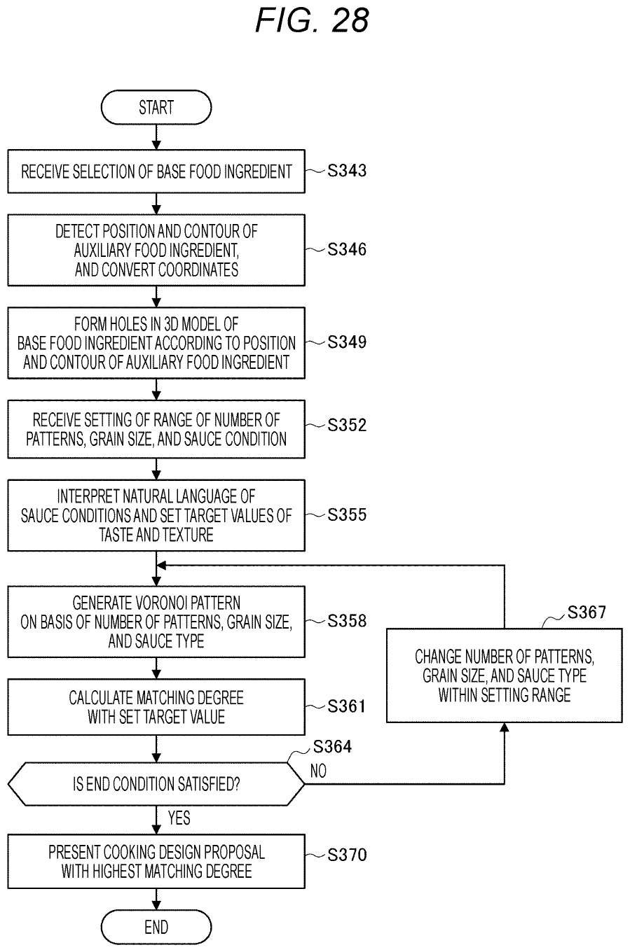

Next, operation processing according to the present embodiment will be described with reference to FIG. 28. FIG. 28 is a flowchart illustrating operation processing of the cooking design (design of a Voronoi pattern of a base food ingredient in a salad plate) according to the present embodiment.

As illustrated in FIG. 28, first, the cooking design generation unit 116 receives a selection operation of a base food ingredient by the user (step S343).

Next, the cooking design generation unit 116 analyzes a captured image obtained by imaging an auxiliary food ingredient (food ingredient to be served together with the base food ingredient) placed at an arbitrary position on the plate by the user with the camera 20, detects a position and a contour of the auxiliary food ingredient, and converts the position and the contour into coordinates of the base food ingredient to be processed (step S346).

Next, the cooking design generation unit 116 forms a circular hole according to the position and contour of the auxiliary food ingredient in the 3D model of the base food ingredient (step S349).

Next, the cooking design generation unit 116 receives user's setting of the pattern number range, the grain size, and the sauce conditions (step S352).

Next, cooking design generation unit 116 interprets the natural language set as the sauce condition with the learned language model, and sets target values of taste and texture (step S355). For example, the cooking design generation unit 116 may set a target value of “a thick sauce with high viscosity (2.0 Pa·s or more)” from an onomatopoeic word “torotoro” by using a learned language model. Note that the list of the sauce to be used is preset, and information on the taste and viscosity of each sauce and the range (hole size) of the size of the Voronoi pattern is prepared.

Next, the cooking design generation unit 116 generates a cooking design proposal (layout of the Voronoi pattern for the main food ingredient) by Voronoi generation algorithm on the basis of the number of patterns, the grain size, and the sauce type within the range of the target value (step S358). The target values are, for example: the total number of Voronoi patterns of grains, sauce 1, and sauce 2 is in the range of 50 to 70; the grain size is in the range of 5 to 8 mm; the total surface area of the grains, sauce 1, and sauce 2 is equal to or less than the surface area of the base food ingredient (radish with holes); and the sauce type has a viscosity of 2.0 Pa·s or more.

Subsequently, the cooking design generation unit 116 calculates a matching degree between the generated cooking design proposal and the target values of the conditionally set number of patterns, grain size, and sauce conditions (step S361).

Next, in a case where the end condition is not satisfied (step S364/No), the cooking design generation unit 116 changes the number of patterns, the grain size, and the type of the sauce within the setting range (step S367), and generates the Voronoi pattern on the basis of the changed number of patterns, the grain size, and the type of the sauce (step S358).

Steps S358 to 367 described above are repeated until the end condition is satisfied. The end condition is, for example, the end of all combinations in the case of an exhaustive search, or a case where a preset matching degree is reached in the case of a genetic algorithm or the like.

Then, when the end condition is satisfied (step S364/Yes), the cooking design generation unit 116 presents a cooking design proposal having the highest matching degree by an image generated by simulation (step S370). The user can check the cooking design proposal and use it for actual cooking processing.

Specifically, the base food ingredient is processed based on the cooking design proposal by cutting with a CNC milling machine, a laser, or the like. The device cooperation unit 117 controls the processing device such that, among the Voronoi patterns, holes to be filled with sauce are cut with a parameter of strength that completely cuts through, while the grain portions are not cut through but are incised with a parameter of strength such that they separate by chewing. In addition, the portion of the grain may be processed such that a part of the periphery of the grain is left as a tab, and the other portion is cut out. In addition, the sauce is poured into the portion of the sauce manually or by a cooking robot or the like after a hole is made in the food ingredient.

The design of the base food ingredient by the Voronoi pattern has been described above. Note that various examples of the arrangement of the grains and the sauce are conceivable. The present invention is not limited to the example illustrated in FIG. 27, and for example, in the base food ingredient, several granular masses may be randomly arranged, and then holes into which the sauce is injected or holes into which no sauce is injected may be arranged around each mass. In addition, in the present embodiment, the Voronoi pattern is used as the processing pattern, but the processing pattern is not limited thereto, and for example, a circular pattern may be used.

Furthermore, the cooking design generation unit 116 may predict the cooking processing result by the cooking processing result prediction unit 112 and include the prediction result in the cooking design proposal. For example, the moisture content or the like of the base food ingredient may affect the cutting result. The cooking design generation unit 116 predicts, by the cooking processing result prediction unit 112, a result of cutting processing with the designed Voronoi pattern using the learned processing prediction model according to the moisture content of the base food ingredient and the like, and uses the prediction result for a cooking design proposal to be presented to the user.

### (3) Application Example

In the present embodiment, as an application example of the cooking design using the Voronoi pattern, there is a meal for elderly people, infants, and patients. In general chopped food, food ingredients are finely cut into sizes according to the severity of symptoms and mixed with a viscous sauce to make swallowing easier; however, in this case, chewing is reduced, which may lead to decreased saliva secretion and diminished taste perception. With the cooking design using the Voronoi pattern according to the present embodiment, it is possible to improve the design quality of chopped food. Specifically, the base food ingredient with a Voronoi pattern as illustrated in FIG. 27 maintains its shape even when lifted (the sauce portions form a film over the holes due to the viscosity of the sauce, and the grain portions are not cut through but are incised with a parameter of strength such that they separate by chewing), but when chewed, the grains crumble and separate, intertwining with the sauce. In this way, chewing is promoted, thereby enhancing tastiness. In addition, it is also possible to finely customize the grain size and the viscosity of the sauce according to the symptoms.

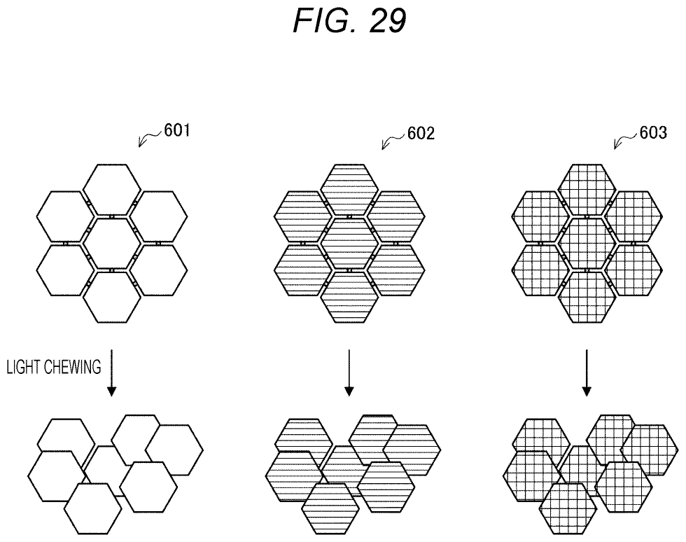

The design of the grain and texture by cutting processing according to the present embodiment is not limited to the example illustrated in FIG. 27. FIG. 29 is a diagram illustrating an example in which mechanical characteristics (hardness) of texture according to the present embodiment are combined. In the cooking design 601 illustrated on the left in FIG. 29, the food ingredients are cut into a hexagonal pattern, but the tabs are left to be connected to each other to form the entire shape, and the tabs are detached by light chewing and become granular. The cooking design 602 illustrated in the center of FIG. 29 is an example in which a horizontal line pattern is engraved in a hexagonal portion, and the texture of the grains is softer than the cooking design 601. Furthermore, the cooking design 603 illustrated on the right in FIG. 29 is an example in which a grid-like pattern is engraved in a hexagonal portion, and the texture is softer than the cooking design 602.

### <4-3. Third Cooking Design Presentation Example>

As an example of a dish, a food ingredient may be used as a container into which a sauce or the like is injected. A cooking design of such a vessel will be described.

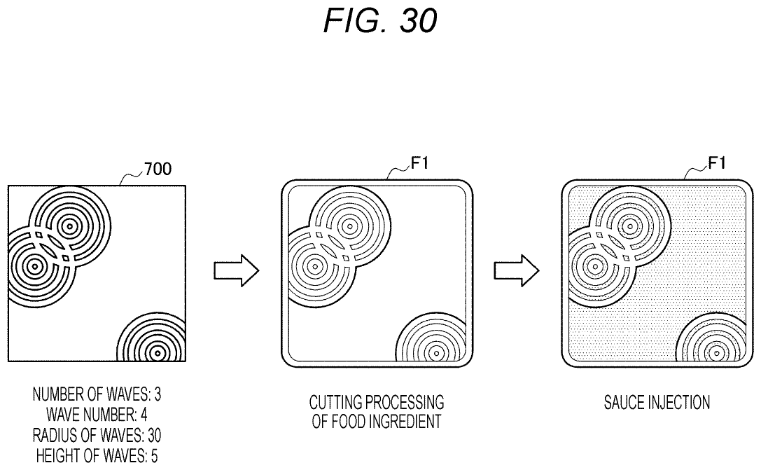

FIG. 30 is a diagram for explaining a cooking design of a container-type food ingredient according to the present embodiment. As illustrated on the left of FIG. 30, the cooking design generation unit 116 can generate the cooking design 700 with a wave pattern on the basis of setting of parameters such as the number of waves, the wave number, the radius of waves, and the height of waves.

Next, in cooperation with the processing device by the device cooperation unit 117, for example, the cooking design 700 is cut as illustrated in the center of FIG. 30 with respect to the rectangular parallelepiped food ingredient F1, and the container-type food ingredient is created. Then, as illustrated in the right of FIG. 30, the sauce is injected into the cut food ingredient F1 and is provided as a container-type food ingredient.

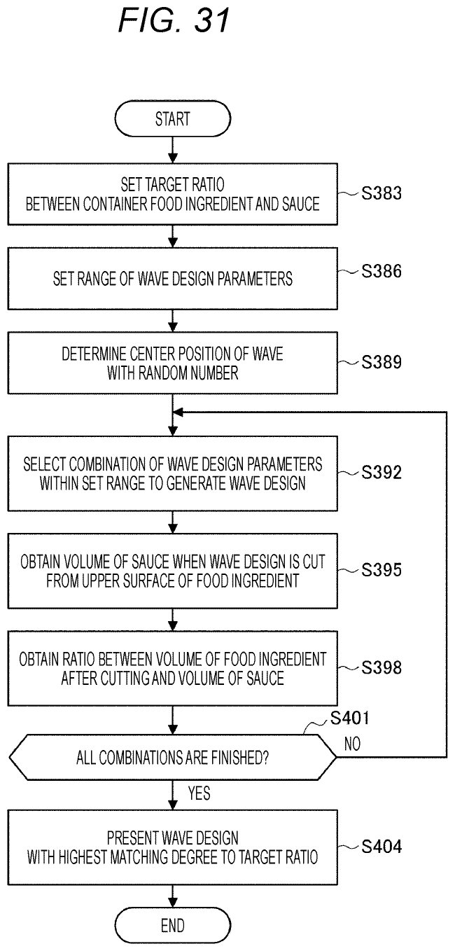

Furthermore, the cooking design generation unit 116 can also generate a cooking design in which the ratio between the container-type food ingredients and the sauce is set to a predetermined golden ratio (which can be set in advance). Hereinafter, description will be given with reference to FIG. 31.

FIG. 31 is a flowchart illustrating an example of a flow of generation processing of a design of a container-type food ingredient according to the present embodiment. As illustrated in FIG. 31, first, a target ratio of a container food ingredient and a sauce is set (step S383). Note that, in the present embodiment, as an example, the container food ingredient is a rectangular parallelepiped, and the shape (size or volume) is fixed. The user can set the ratio target of the container food ingredient and the sauce to 1:10, for example.

Next, a range of the design parameter of the wave is set (step S386). For example, a range of parameters such as the number of waves, the wave number, the radius of waves, and the height of waves is set by the user.

Next, the cooking design generation unit 116 determines the center position of the wave in the container-type food ingredient by, for example, a random number (step S389).

Next, the cooking design generation unit 116 selects a combination of the wave design parameters within the setting range and generates a wave design for the container-type food ingredient (step S392).

Next, the cooking design generation unit 116 obtains the volume of the sauce that can be poured into the container-type food ingredient when the wave design is cut from the upper surface of the container-type food ingredient (step S395). Furthermore, the cooking design generation unit 116 obtains a ratio between the volume of the cut container-type food ingredient and the volume of the sauce described above (step S398).

Subsequently, the processing of steps S392 to S398 described above is repeated until all combinations are completed (step S401).

When all combinations are completed (step S401/Yes), the cooking design generation unit 116 presents a wave design (cooking design) having a high matching degree with respect to the target ratio (step S404). Note that the cooking design generation unit 116 may predict the cooking processing result by the cooking processing result prediction unit 112 and include the prediction result in the cooking design proposal. For example, the moisture content or the like of the container-type food ingredient may affect the cutting result. The cooking design generation unit 116 predicts, by the cooking processing result prediction unit 112, a result of cutting processing with the designed wave design using the learned processing prediction model according to the moisture content or the like of the container-type food ingredient, and uses the prediction result as a cooking design proposal to be presented to the user.

### <<5. Supplement>>

The preferred embodiment of the present disclosure has been described in detail above with reference to the accompanying drawings, but the present technology is not limited to such examples. It is obvious that a person having ordinary knowledge in the technical field of the present disclosure can conceive various changes or modifications within the scope of the technical idea described in the claims, and it is naturally understood that these also belong to the technical scope of the present disclosure.

The above-described embodiment is used as, for example, a study tool when a chef or a cooking expert designs a new dish. In addition, the above-described embodiment is used as a cooking design tool assuming cooking by a cooking robot or a digital device. In addition, the above-described embodiment is also used as a tool for improving and customizing dietary restrictions (such as chopped food) of an elderly person, an infant, a patient, and the like. Furthermore, the above-described embodiment is used as a design tool that also supports prediction of a result of digital cooking processing, which is difficult to understand from conventional cooking experience. In addition, since a combination of food ingredients is also selected, it is possible to receive proposal of a combination of new food ingredients such as an alternative protein and cultured meat, and further, cooking processing prediction for the combination of new food ingredients can also be presented. Furthermore, the above-described embodiment can also be applied to entertainment and game applications for designing dishes. For example, the present embodiment can also provide a children's food raising application in which a cooking robot automatically cooks a dish designed in a game.

Furthermore, it is also possible to create one or more computer programs for causing hardware such as the CPU, the ROM, and the RAM built in the information processing apparatus 10 described above to exhibit the functions of the information processing apparatus 10. Furthermore, a computer-readable storage medium storing the one or more computer programs is also provided.

Furthermore, the effects described in the present specification are merely illustrative or exemplary, and are not restrictive. That is, the technology according to the present disclosure can exhibit other effects obvious to those skilled in the art from the description of the present specification together with or instead of the above effects.

Note that the present technology can also have the following configurations.

(1)

An information processing apparatus including:
a prediction unit that predicts a processing result of a food ingredient on the basis of data of the food ingredient and information regarding cooking processing for the food ingredient; and
an output unit that outputs a processing result prediction image indicating the processing result predicted.
   (2)

The information processing apparatus according to (1), in which the cooking processing includes heating processing, cutting processing, or engraving processing performed on the food ingredient by a digital fabrication device.

(3)

The information processing apparatus according to (1) or (2), in which the data of the food ingredient includes a captured image of the food ingredient, a type of the food ingredient, or component information of the food ingredient.

(4)

The information processing apparatus according to any one of (1) to (3), in which
the information regarding the cooking processing of the food ingredient includes a processing pattern, and
the prediction unit predicts the processing result when the cooking processing with the processing pattern is performed on the food ingredient, using a learned processing prediction model.
   (5)

The information processing apparatus according to (4), further including
a learning unit that generates the processing prediction model by learning a relationship between a plurality of processing patterns and a plurality of processing result captured images obtained by capturing an image of a result of cooking and processing the food ingredient with the plurality of processing patterns.
   (6)

The information processing apparatus according to (4), further including
a learning unit that generates the processing prediction model by learning a relationship between a combination of a food ingredient captured image obtained by imaging the food ingredient before cooking processing and a processing pattern and a combination of a processing result captured image obtained by imaging a result of cooking and processing the food ingredient based on the food ingredient captured image and the processing pattern.
   (7)

The information processing apparatus according to (4), further including
a learning unit that generates the processing prediction model by learning a relationship between a plurality of processing patterns and a plurality of processing result captured images obtained by imaging a result of cooking and processing the food ingredient having a moisture content level predetermined according to the processing patterns.
   (8)

The information processing apparatus according to (7), in which
the data of the food ingredient includes data of a moisture content, and
the prediction unit generates the processing result prediction image using the learned processing prediction model on the basis of the moisture content level of the food ingredient and the processing pattern.
   (9)

The information processing apparatus according to (4), in which
the prediction unit predicts a processing pattern for obtaining a processing result indicated by the processing result prediction image using the data of the food ingredient, the processing result prediction image as a target, and the learned processing prediction model, and
the output unit outputs an image of the processing pattern predicted.
   (10)

The information processing apparatus according to (1), further including
a generation unit that generates one or more cooking design proposals on the basis of the data of the food ingredient and one or more cooking conditions related to the cooking processing, in which
the output unit outputs an image of the cooking design proposals.
   (11)

The information processing apparatus according to (10), in which the cooking conditions are input as a numerical value, a natural language, or a schematic diagram.

(12)

The information processing apparatus according to (10) or (11), in which the cooking conditions include intention of a user or preference or restriction of a customer.

(13)

The information processing apparatus according to any one of (10) to (12), in which
the generation unit generates a plurality of cooking design proposals, and
the output unit outputs a predetermined number of cooking design proposals having high matching degree with the cooking conditions among the plurality of cooking design proposals.
   (14)

The information processing apparatus according to any one of (10) to (13), in which the generation unit generates the cooking design proposal by 3D simulation, using a main food ingredient, a sub material selected for the main food ingredient, and a processing pattern used for cooking processing by a digital fabrication device.

(15)

The information processing apparatus according to any one of (10) to (14), in which the generation unit generates the image of the cooking design proposal including prediction of the processing result of the food ingredient by the prediction unit.

(16)

The information processing apparatus according to any one of (10) to (15), further including: a device cooperation unit that performs control to transmit information of the cooking processing to a digital fabrication device on the basis of the cooking design proposal selected by a user.

(17)

A control method including: by a processor,
predicting a processing result of a food ingredient on the basis of data of the food ingredient and information regarding cooking processing for the food ingredient; and
outputting a processing result prediction image indicating the processing result predicted.
   (18)

A program for causing a computer to function as:
a prediction unit that predicts a processing result of a food ingredient on the basis of data of the food ingredient and information regarding cooking processing for the food ingredient; and
an output unit that outputs a processing result prediction image indicating the processing result predicted.

### REFERENCE SIGNS LIST

10 Information processing apparatus
110 Control unit
111 Learning unit
112 Cooking processing result prediction unit
113 Processing pattern prediction unit
114 Material selection unit
115 Processing pattern generation unit
116 Cooking design generation unit
117 Device cooperation unit
120 Communication unit
130 Operation input unit
140 Display unit
150 Storage unit

1. An information processing apparatus comprising:
a prediction unit that predicts a processing result of a food ingredient on a basis of data of the food ingredient and information regarding cooking processing for the food ingredient; and
an output unit that outputs a processing result prediction image indicating the processing result predicted.

2. The information processing apparatus according to claim 1, wherein the cooking processing includes heating processing, cutting processing, or engraving processing performed on the food ingredient by a digital fabrication device.

3. The information processing apparatus according to claim 1, wherein the data of the food ingredient includes a captured image of the food ingredient, a type of the food ingredient, or component information of the food ingredient.

4. The information processing apparatus according to claim 1, wherein
the information regarding the cooking processing of the food ingredient includes a processing pattern, and
the prediction unit predicts the processing result when the cooking processing with the processing pattern is performed on the food ingredient, using a learned processing prediction model.

5. The information processing apparatus according to claim 4, further comprising
a learning unit that generates the processing prediction model by learning a relationship between a plurality of processing patterns and a plurality of processing result captured images obtained by capturing an image of a result of cooking and processing the food ingredient with the plurality of processing patterns.

6. The information processing apparatus according to claim 4, further comprising
a learning unit that generates the processing prediction model by learning a relationship between a combination of a food ingredient captured image obtained by imaging the food ingredient before cooking processing and a processing pattern and a combination of a processing result captured image obtained by imaging a result of cooking and processing the food ingredient based on the food ingredient captured image and the processing pattern.

7. The information processing apparatus according to claim 4, further comprising
a learning unit that generates the processing prediction model by learning a relationship between a plurality of processing patterns and a plurality of processing result captured images obtained by imaging a result of cooking and processing the food ingredient having a moisture content level predetermined according to the processing patterns.

8. The information processing apparatus according to claim 7, wherein
the data of the food ingredient includes data of a moisture content, and
the prediction unit generates the processing result prediction image using the learned processing prediction model on a basis of the moisture content level of the food ingredient and the processing pattern.

9. The information processing apparatus according to claim 4, wherein
the prediction unit predicts a processing pattern for obtaining a processing result indicated by the processing result prediction image using the data of the food ingredient, the processing result prediction image as a target, and the learned processing prediction model, and
the output unit outputs an image of the processing pattern predicted.

10. The information processing apparatus according to claim 1, further comprising
a generation unit that generates one or more cooking design proposals on a basis of the data of the food ingredient and one or more cooking conditions related to the cooking processing, wherein
the output unit outputs an image of the cooking design proposals.

11. The information processing apparatus according to claim 10, wherein the cooking conditions are input as a numerical value, a natural language, or a schematic diagram.

12. The information processing apparatus according to claim 10, wherein the cooking conditions include intention of a user or preference or restriction of a customer.

13. The information processing apparatus according to claim 10, wherein
the generation unit generates a plurality of cooking design proposals, and
the output unit outputs a predetermined number of cooking design proposals having high matching degree with the cooking conditions among the plurality of cooking design proposals.

14. The information processing apparatus according to claim 10, wherein the generation unit generates the cooking design proposal by 3D simulation, using a main food ingredient, a sub material selected for the main food ingredient, and a processing pattern used for cooking processing by a digital fabrication device.

15. The information processing apparatus according to claim 10, wherein the generation unit generates the image of the cooking design proposal including prediction of the processing result of the food ingredient by the prediction unit.

16. The information processing apparatus according to claim 10, further comprising: a device cooperation unit that performs control to transmit information of the cooking processing to a digital fabrication device on a basis of the cooking design proposal selected by a user.

17. A control method comprising: by a processor,
predicting a processing result of a food ingredient on a basis of data of the food ingredient and information regarding cooking processing for the food ingredient; and
outputting a processing result prediction image indicating the processing result predicted.

18. A program for causing a computer to function as:
a prediction unit that predicts a processing result of a food ingredient on a basis of data of the food ingredient and information regarding cooking processing for the food ingredient; and
an output unit that outputs a processing result prediction image indicating the processing result predicted.
